(19) United States
(12) Patent Application Publication
(10) Pub. No.: US 2026/0268050 A1
(43) Pub. Date: Sep. 10, 2026

(54) TRAINING DEVICE, INFORMATION PROCESSING APPARATUS, SUBSTRATE PROCESSING DEVICE, TRAINING METHOD AND PROCESSING CONDITION DETERMINATION METHOD

(71) Applicant: SCREEN HOLDINGS CO., LTD., Kyoto (JP)

(72) Inventors: Masahiro TOKUYAMA, Kyoto-shi, Kyoto (JP); Kensuke SHINOHARA, Kyoto-shi, Kyoto (JP)

(21) Appl. No.: 19/167,379

(22) PCT Filed: Mar. 12, 2024
(86) PCT No.: PCT/JP2024/009596

§ 371 Date: Sep. 21, 2025

(30) Foreign Application Priority Data
Mar. 24, 2023 (JP) 2023-048554
Nov. 13, 2023 (JP) 2023-193281

(51) Int. Cl. G06F 30/30; G06F 30/27; G06N 5/025

(52) U.S. Cl. CPC G06F 30/30; G06F 30/27; G06N 5/025

(57) ABSTRACT

A training device includes a first hardware processor, wherein the first hardware processor acquires a first dataset including a processing condition for a process to be executed by a substrate processing device, and a processing result of the process, generates a pre-processing condition, causes a learning model to execute machine learning using the second dataset, and causes the trained learning model to execute machine learning using the first dataset, with the trained learning model having executed machine learning using the second dataset, and the second dataset includes a pre-processing result that is predicted by a predetermined prediction algorithm based on the pre-processing condition, and the pre-processing condition.

### TECHNICAL FIELD

The present invention relates to a training device, an information processing apparatus, a substrate processing device, a training method and a processing condition determination method. In particular, the present invention relates to a training device that generates a learning model that has executed machine learning, an information processing apparatus that manages a substrate processing device using the learning model, a substrate processing device including the information processing apparatus, a training method executed by the training device, and a processing condition determination method executed by the information processing apparatus.

### BACKGROUND ART

In one of semiconductor manufacturing processes, there is an etching process. In the etching process, the thickness of a film formed on a substrate is adjusted by an etching process of supplying a chemical liquid to the substrate. In this film-thickness adjustment, it is important to execute the etching process such that the entire surface of the substrate is uniformly etched, or to flatten the surface of the substrate in the etching process. In a case in which an etching liquid is discharged from a nozzle to a portion of the substrate, the nozzle is required to be moved in a radial direction with respect to the substrate.

Patent Document 1 describes a liquid processing device that is capable of executing an etching process on a substrate by discharging an etching liquid to the substrate through an etching nozzle. Patent Document 1 describes, by way of example, that in order to make the in-plane temperature distribution of a wafer uniform while the etching process is executed on the center area of a substrate, the etching liquid is discharged while an etching nozzle is moved back and forth repeatedly between a first position and a second position, with the first position being a position at which the etching nozzle is located when the discharged etching liquid passes through the center of the wafer and which is close to the center and with the second position being a position closer to the peripheral portion of the wafer than the position closer to the center.

The etching process is a complicated process in which an processing amount for a film changes according to differences in concentration of an etching liquid, a temperature of the etching liquid and a substrate rotation speed in addition to work for moving a nozzle. Therefore, it is conceivable that a learning model executes machine learning using artificial intelligence and a trained learning model predicts a processing amount.
[Patent Document 1] JP 2015-103656 A

### SUMMARY OF INVENTION

### Technical Problem

It is known that accuracy of a learning model depends on training data to be learned by the learning model. In general, as the training data, a processing condition for actually driving a substrate processing device and a processing result obtained when the substrate processing device is driven according to the processing condition, are used.

However, as training data obtained by an actual process by the substrate processing device, a processing condition biased to a certain characteristic and a processing result of the process executed according to the processing condition might be used. In a case in which a processing condition having a characteristic different from that of the training data is provided to a learning model that has executed machine learning using such training data, the prediction accuracy of the learning model may be degraded. On the other hand, in order to prepare training data having no bias in characteristics, the substrate processing device needs to be actually driven according to a huge number of processing conditions. Therefore, there is a problem that substantial cost and substantial amount of time are required because it is time consuming to perform setting for the substrate processing device and to drive the substrate processing device.

One object of the present invention is to provide a training device capable of generating a highly accurate learning model at low cost.

Another object of the present invention is to provide a training method that enables generation of a highly accurate learning model at low cost.

Yet another object of the present invention is to provide an information processing apparatus that enables presentation of a plurality of processing conditions for a processing result of a complicated process of processing a substrate, and a substrate processing device including the information processing apparatus.

Yet another object of the present invention is to provide a processing condition determination method that enables presentation of a plurality of processing conditions for a processing result of a complicated process of processing a substrate.

### Solution to Problem

(1) A training device according to one aspect of the present invention includes an experimental data acquirer that acquires a first dataset including a processing condition for a process to be executed by a substrate processing device, and a processing result of the process, a pre-processing condition generator that generates a pre-processing condition, a pre-trainer that causes a learning model to execute machine learning using the second dataset, and a learning model generator that causes the trained learning model to execute machine learning using the first dataset, with the trained learning model being made by the pre-trainer to execute machine learning, wherein the second dataset includes a pre-processing result that is predicted by a predetermined prediction algorithm based on the pre-processing condition, and the pre-processing condition.
(2) An information processing apparatus according to another aspect of the present invention that manages the substrate processing device using the learning model, with the learning model being generated by the above-mentioned training device, includes an acquirer that acquires the learning model from the training device, and a processing condition determiner that, in a case in which a prediction processing result satisfies an allowable condition, determines a temporary processing condition as a processing condition for driving the substrate processing device, with the prediction processing result being predicted by the learning model when the temporary processing condition is provided to the learning model.
(3) A substrate processing device according to yet another aspect of the present invention includes the above-mentioned information processing apparatus.
(4) A training method according to yet another aspect of the present invention includes a step of acquiring a first dataset that includes a processing condition for a process executed by a substrate processing device, and a processing result of the process, a step of generating a pre-processing condition, a pre-training step of causing a learning model to execute machine learning using a second dataset, and a learning model generating step of causing the trained learning model to execute machine learning using the first dataset, with the trained learning model executing machine learning in the pre-training step, wherein the second dataset includes a pre-processing result and the pre-processing condition, with the pre-processing result being predicted by a predetermined prediction algorithm based on the pre-processing condition.
(5) A processing condition determination method according to yet another aspect of the present invention executed by an information processing apparatus using the learning model generated by a training device that executes the above-mentioned training method, with the information processing apparatus managing the substrate processing device, includes an acquiring step of acquiring the learning model from the training device, and a processing condition determination step of, in a case in which a prediction processing result satisfies an allowable condition, determining a temporary processing condition as a processing condition for driving the substrate processing device, with the prediction processing result being predicted by the learning model when the temporary processing condition is provided to the learning model.

### Advantageous Effects of Invention

It is possible provide a training device and a training method that enable generation of a highly accurate learning model at low cost. Further, it is possible to provide an information processing apparatus and a processing condition determination method that enable presentation of a plurality of processing conditions for a processing result of a complicated process of processing a substrate, and a substrate processing device including the information processing apparatus.

### BRIEF DESCRIPTION OF THE DRAWINGS

FIG. 1 is a diagram for explaining the configuration of a substrate processing system according to one embodiment of the present invention.

FIG. 2 is a diagram showing one example of the configuration of an information processing apparatus.

FIG. 3 is a diagram showing one example of the configuration of a training device.

FIG. 4 is a diagram showing one example of the functional configuration of the substrate processing system according to the one embodiment.

FIG. 5 is a diagram showing one example of the functions of a prediction device generator.

FIG. 6 is a diagram for explaining a change of a relative position of a nozzle with respect to a substrate in a film process.

FIG. 7 is a diagram showing one example of a nozzle work pattern.

FIG. 8 is a diagram for explaining divided areas.

FIG. 9 is a diagram for explaining compression of a variable condition.

FIG. 10 is a diagram for explaining a prediction algorithm.

FIG. 11 is a flowchart showing one example of a flow of a training process.

FIG. 12 is a flowchart showing one example of a flow of a prediction algorithm generation process.

FIG. 13 is a flowchart showing one example of a flow of a pre-processing condition generation process.

FIG. 14 is a flowchart showing one example of a flow of a pre-training process.

FIG. 15 is a flowchart showing one example of a flow of a learning model generation process.

FIG. 16 is a flowchart showing one example of a flow of a processing condition determination process.

FIG. 17 is a diagram showing one example of the functional configuration of a substrate processing system in a modified example.

FIG. 18 is a diagram showing one example of the functions of a prediction device generator in the modified example.

FIG. 19 is a diagram showing one example of the detailed functions of a pre-processing condition generator.

FIG. 20 is a diagram for explaining one example of a result of clustering.

FIG. 21 is a flowchart showing one example of a flow of a training process in the modified example.

FIG. 22 is a flowchart showing one example of a flow of a pre-processing condition generation process.

FIG. 23 is a flowchart showing one example of a flow of a second dataset generation process.

FIG. 24 is a flowchart showing one example of a flow of a pre-training process in the modified example.

### DESCRIPTION OF EMBODIMENTS

A substrate processing system according to one embodiment of the present invention will be described below in detail with reference to the drawings. In the following description, a substrate refers to a semiconductor substrate (semiconductor wafer), a substrate for an FPD (Flat Panel Display) such as a liquid crystal display device or an organic EL (Electro Luminescence) display device, a substrate for an optical disc, a substrate for a magnetic disc, a substrate for a magneto-optical disc, a substrate for a photomask, a ceramic substrate, a substrate for a solar battery, or the like. 10

### (1) Overall Configuration of Substrate Processing System

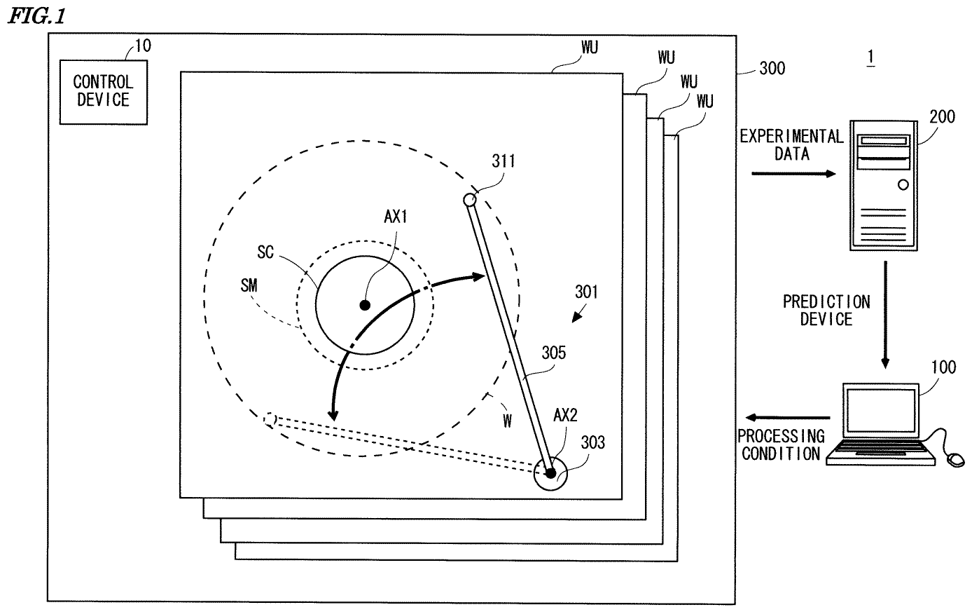

FIG. 1 is a diagram for explaining the configuration of the substrate processing system according to the one embodiment of the present invention. The substrate processing system 1 of FIG. 1 includes an information processing apparatus 100, a training device 200 and a substrate processing device 300. The training device 200 is a server, for example, and the information processing apparatus 100 is a personal computer, for example.

The training device 200 and the information processing apparatus 100 are used to manage the substrate processing device 300. The number of substrate processing devices 300 managed by the training device 200 and the information processing apparatus 100 is not limited to one, and a plurality of substrate processing devices 300 may be managed by the training device 200 and the information processing apparatus 100.

In the substrate processing system 1 according to the present embodiment, the information processing apparatus 100, the training device 200 and the substrate processing device 300 are connected to one another by a wired communication line, a wireless communication line or a communication network. The information processing apparatus 100, the training device 200 and the substrate processing device 300 are respectively connected to a network and can transmit and receive data to and from one another. As the network, a Local Area Network (LAN) or a Wide Area Network (WAN) is used, for example. Further, the network may be the Internet. Further, the information processing apparatus 100 and the substrate processing device 300 may be connected to each other via a dedicated communication network. The connection state of the network may be wired or wireless.

The training device 200 is not necessarily required to be connected to the substrate processing device 300 or the information processing apparatus 100 via a communication line or a communication network. In this case, data generated in the substrate processing device 300 may be transferred to the training device 200 via a recording medium. Further, data generated in the training device 200 may be transferred to the information processing apparatus 100 via a recording medium.

In the substrate processing device 300, a display device, a speech output device and an operation unit (not shown) are provided. The substrate processing device 300 runs according to a predetermined processing condition (processing recipe) of the substrate processing device 300.

### (2) Outline of Substrate Processing Device

The substrate processing device 300 includes a control device 10 and a plurality of substrate processing units WU. The control device 10 controls the plurality of substrate processing units WU. Each of the plurality of substrate processing units WU executes a film process on a substrate W by supplying a processing liquid to the substrate W on which a film is formed. The film process to be executed on the substrate W by supply of a processing liquid to the substrate W on which a film is formed is an example of a process executed in the substrate processing device. While the substrate W to be processed has the diameter of 300 mm in the present embodiment, the present invention is not limited to this. The processing liquid includes an etching liquid, and the substrate processing unit WU executes an etching process. The etching liquid is a chemical liquid. The etching liquid is a fluoronitric acid (a liquid mixture of hydrofluoric acid (HF) and nitric acid (HNO₃), hydrofluoric acid, buffered hydrofluoric acid (BHF), ammonium fluoride, HFEG (a liquid mixture of hydrofluoric acid and ethylene glycol) or phosphoric acid (H₃PO₄), for example.

The substrate processing unit WU includes a spin chuck SC, a spin motor SM, a nozzle 311 and a nozzle moving mechanism 301. The spin chuck SC horizontally holds the substrate W. The substrate W is held by the spin chuck SC such that a first rotation axis AX1 of the spin motor SM coincides with the center of the substrate W. The spin motor SM has the first rotation axis AX1. The first rotation axis AX1 extends in an upward-and-downward direction. The spin chuck SC is attached to the upper end portion of the first rotation axis AX1 of the spin motor SM. When the spin motor SM rotates, the spin chuck SC rotates about the first rotation axis AX1. The spin motor SM is a stepping motor. The substrate W held by the spin chuck SC rotates about the first rotation axis AX1. Therefore, the rotation speed of the substrate W is equal to the rotation speed of the stepping motor. In a case in which an encoder that generates a rotation-speed signal indicating a rotation speed of the spin motor SM is provided, the rotation speed of the substrate W may be acquired from the rotation-speed signal generated by the encoder. In this case, a motor other than the stepping motor can be used as the spin motor SM.

The nozzle 311 supplies the etching liquid to an obverse surface (upper surface) of the substrate W held by the spin chuck SC. The etching liquid is supplied from an etching liquid supplier (not shown) to the nozzle 311. The nozzle 311 discharges the etching liquid to the obverse surface of the rotating substrate W.

The nozzle moving mechanism 301 moves the nozzle 311 in a substantially horizontal direction. Specifically, the nozzle moving mechanism 301 has a nozzle motor 303 having a second rotation axis AX2 and a nozzle arm 305. The nozzle motor 303 is arranged such that the second rotation axis AX2 extends in a substantially vertical direction. The nozzle arm 305 has a longitudinal shape extending linearly. One end of the nozzle arm 305 is attached to the upper end of the second rotation axis AX2 such that the longitudinal direction of the nozzle arm 305 is different from the direction in which the second rotation axis AX2 extends. The nozzle 311 is attached to the other end of the nozzle arm 305 such that an outlet port for the etching liquid is directed downwardly.

When the nozzle motor 303 works, the nozzle arm 305 rotates about the second rotation axis AX2 in a horizontal plane. Thus, the nozzle 311 attached to the other end of the nozzle arm 305 moves (turns) in the horizontal direction about the second rotation axis AX2. The nozzle 311 discharges the etching liquid toward the substrate W while moving in the horizontal direction. The nozzle motor 303 is a stepping motor, for example.

The control device 10 includes a CPU (Central Processing Unit) and a memory, and controls the substrate processing device 300 as a whole by execution by the CPU of a program stored in the memory. The control device 10 controls the spin motor SM and the nozzle motor 303.

The training device 200 receives experimental data from the substrate processing device 300. The training device 200 generates a prediction device using the experimental data, and outputs the prediction device to the information processing apparatus 100.

The information processing apparatus 100 determines, using the prediction device, a processing condition for processing the substrate to be processed by the substrate processing device 300. The information processing apparatus 100 outputs the determined processing condition to the substrate processing device 300.

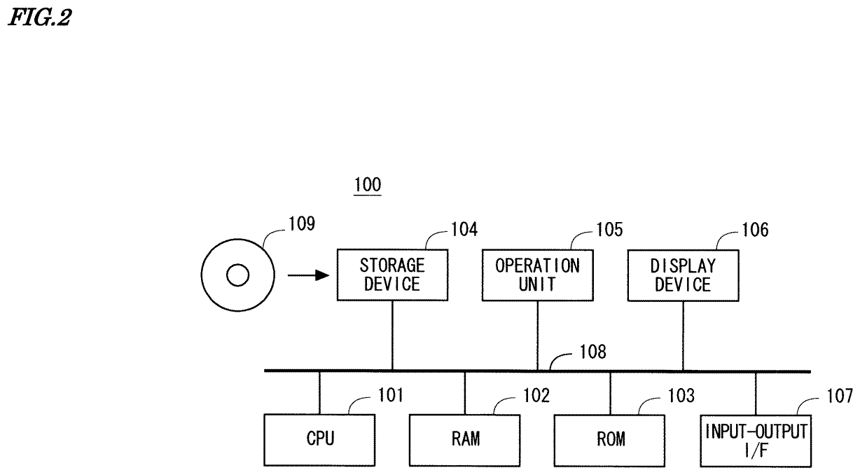

FIG. 2 is a diagram showing one example of the configuration of the information processing apparatus. With reference to FIG. 2, the information processing apparatus 100 includes a CPU 101, a RAM (Random Access Memory) 102, a ROM (Read Only Memory) 103, a storage device 104, an operation unit 105, a display device 106 and an input-output I/F (interface) 107. The CPU 101, the RAM 102, the ROM 103, the storage device 104, the operation unit 105, the display device 106 and the input-output I/F 107 are connected to a bus 108.

The RAM 102 is used as a work area for the CPU 101. A system program is stored in the ROM 103. The storage device 104 includes a storage medium such as a hard disc or a semiconductor memory and stores a program. A program may be stored in the ROM 103 or another external storage device.

A CD-ROM 109 is attachable to and detachable from the storage device 104. A recording medium storing a program to be executed by the CPU 101 is not limited to the CD-ROM 109. It may be an optical disc (MO (Magnetic Optical Disc)/MD (Mini Disc)/DVD (Digital Versatile Disc)), an IC card, an optical card, and a semiconductor memory such as a mask ROM or an EPROM (Erasable Programmable ROM). Further, the CPU 101 may download a program from a computer connected to the network to store the program in the storage device 104. Alternatively, the computer connected to the network may write a program in the storage device 104, and the program stored in the storage device 104 may be loaded into the RAM 102 to be executed in the CPU 101. The program referred to here includes not only a program directly executable by the CPU 101 but also a source program, a compressed program, an encrypted program and the like.

The operation unit 105 is an input device such as a keyboard, a mouse or a touch panel. A user can provide a predetermined instruction to the information processing apparatus 100 by operating the operation unit 105. The display device 106 is a display device such as a liquid crystal display device and displays a GUI (Graphical User Interface) or the like for receiving an instruction from the user. The input-output I/F 107 is connected to the network.

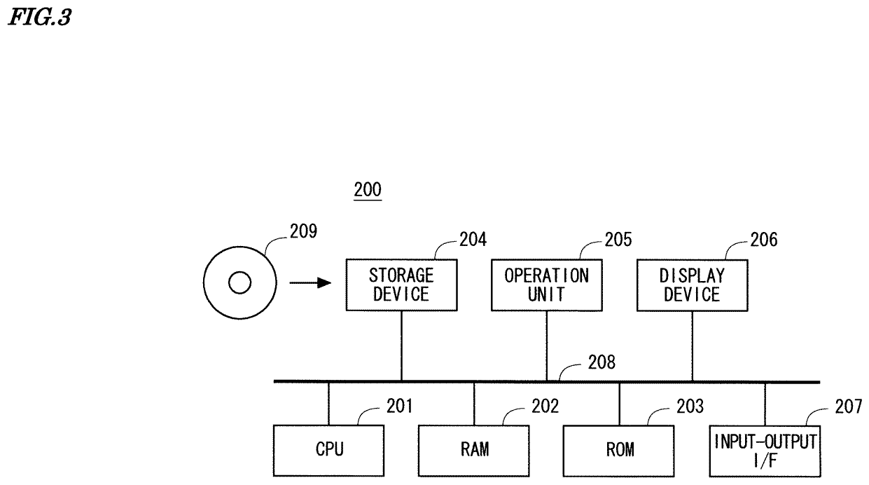

FIG. 3 is a diagram showing one example of the configuration of the training device. With reference to FIG. 3, the training device 200 includes a CPU 201, a RAM 202, a ROM 203, a storage device 204, an operation unit 205, a display device 206 and an input-output I/F 207. The CPU 201, the RAM 202, the ROM 203, the storage device 204, the operation unit 205, the display device 206 and the input-output I/F 207 are connected to a bus 208.

The RAM 202 is used as a work area for the CPU 201. A system program is stored in the ROM 203. The storage device 204 includes a storage medium such as a hard disc or a semiconductor memory and stores a program. The program may be stored in the ROM 203 or another external storage device. A CD-ROM 209 is attachable to and detachable from the storage device 204.

The operation unit 205 is an input device such as a keyboard, a mouse or a touch panel. The input-output I/F 207 is connected to the network.

### (3) Functional Configuration of Substrate Processing System

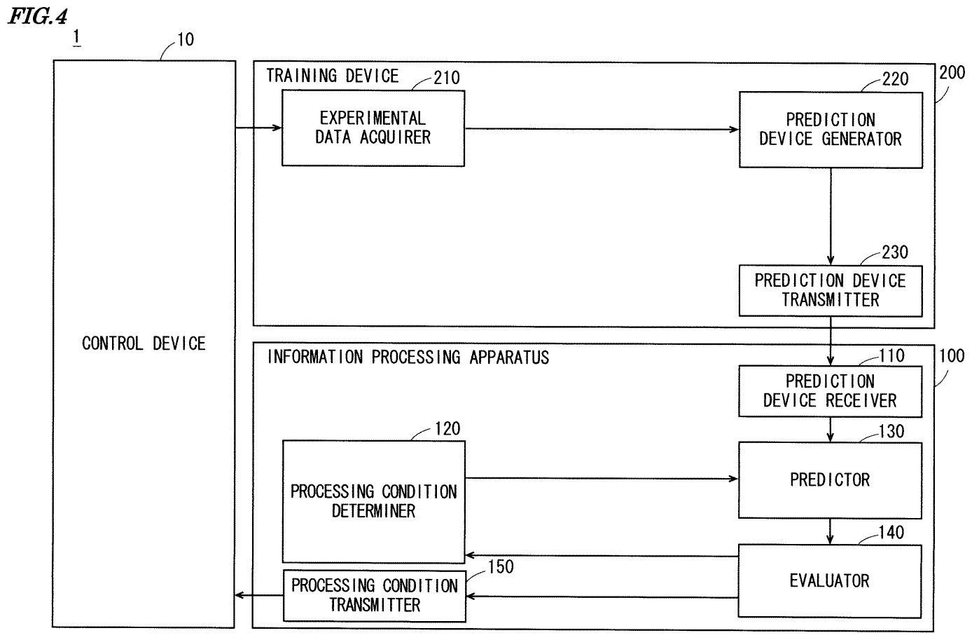

FIG. 4 is a diagram showing one example of the functional configuration of the substrate processing system according to the one embodiment. With reference to FIG. 4, the control device 10 included in the substrate processing device 300 controls the substrate processing unit WU to execute a film process on the substrate W according to a processing condition in a processing period of time. The processing period of time is the period of time defined in regard to the film process for the substrate. In the present embodiment, the processing period of time is the period of time during which the nozzle 311 discharges the etching liquid to the substrate W. The processing condition is a condition used when the substrate processing unit WU executes the film process.

The processing condition includes a temperature of the etching liquid, a concentration of the etching liquid, a flow rate of the etching liquid, a rotation speed of the substrate W and a position of the nozzle 311. A concentration of the etching liquid is indicated by a mixing ratio of a plurality of chemical liquids. A position of the nozzle 311 is indicated by a relative position of the nozzle 311 with respect to the substrate W at each of a plurality of points in time during execution of the film process. A relative position of the nozzle 311 with respect to the substrate is indicated by a rotation angle of the nozzle motor 303.

A processing condition includes a fixed condition that does not vary over time and a variable condition that varies over time. In the present embodiment, the fixed conditions are a temperature of the etching liquid, a concentration of the etching liquid, a flow rate of the etching liquid, a rotation speed of the substrate W, and the variable condition is a relative position of the nozzle 311 with respect to the substrate W during execution of the film process.

With reference back to FIG. 4, the training device 200 includes an experimental data acquirer 210, a prediction device generator 220 and a prediction device transmitter 230. The functions included in the training device 200 are implemented by execution by the CPU 201 included in the training device 200 of a trained model generation program stored in the RAM 202.

The experimental data acquirer 210 acquires experimental data from the substrate processing device 300. The experimental data includes a processing condition, and a processing result representing a result of the film process executed by the substrate processing device 300 on the substrate W according to the processing condition.

The prediction device generator 220 receives the experimental data from the experimental data acquirer 210. The prediction device generator 220 generates a prediction device based on the experimental data, and outputs the generated prediction device to the prediction device transmitter 230. Details of the prediction device generator 220 will be described below. The prediction device transmitter 230 transmits the prediction device generated by the prediction device generator 220 to the information processing apparatus 100.

The information processing apparatus 100 includes a prediction device receiver 110, a processing condition determiner 151, a predictor 130, an evaluator 140 and a processing condition transmitter 150. The functions included in the information processing apparatus 100 are implemented by execution, by the CPU 101 included in the information processing apparatus 100, of a processing condition determination program stored in the RAM 102.

The prediction device receiver 110 receives a prediction device transmitted from the training device 200 and outputs the received prediction device to the predictor 130. The processing condition determiner 120 determines a processing condition for the substrate W to be processed by the substrate processing device 300, and outputs a variable condition included in the processing condition, and a fixed condition included in the processing condition to the predictor 130.

The predictor 130 predicts a prediction processing result based on the variable condition and the fixed condition using the prediction device. The predictor 130 inputs the variable condition and the fixed condition received from the processing condition determiner 120 to the prediction device, and outputs the prediction processing result output by the prediction device to the evaluator 140.

The evaluator 140 evaluates the prediction processing result received from the predictor 130, and outputs an evaluation result to the processing condition determiner 120. In detail, the evaluator 140 acquires a film-thickness characteristic obtained before the substrate W to be processed by the substrate processing device 300 is processed. The evaluator 140 calculates a film-thickness characteristic predicted to be obtained after the etching process based on the prediction processing result received from the predictor 130, and the film-thickness characteristic of the substrate W before the process, and compares the calculated film-thickness characteristic with a target film-thickness characteristic. When a comparison result satisfies an evaluation criterion, the processing condition determined by the processing condition determiner 120 is output to the processing condition transmitter 150 as a processing condition for the substrate W to be processed by the substrate processing device 300. For example, the evaluator 140 calculates a deviation characteristic and determines whether the deviation characteristic satisfies the evaluation criterion. The deviation characteristic is the difference between the film-thickness characteristic of the substrate W obtained after the etching process and the target film-thickness characteristic. The evaluation criterion can be arbitrarily defined. For example, in regard to the deviation characteristic, the evaluation criterion may be that the maximum value of difference is equal to or smaller than a threshold value, or that the average of differences is equal to or smaller than the threshold value.

The processing condition transmitter 150 transmits the processing condition received from the processing condition determiner 120 to the control device 10 of the substrate processing device 300. The substrate processing device 300 processes the substrate W according to the processing condition.

In a case in which the evaluation result does not satisfy the evaluation criterion, the evaluator 140 outputs the evaluation result to the processing condition determiner 120. The evaluation result includes a film-thickness characteristic predicted to be obtained after the etching process, or the difference between the film-thickness characteristic to be obtained after the etching process and the target film-thickness characteristic.

In response to receiving the evaluation result from the evaluator 140, the processing condition determiner 120 determines a new processing condition for prediction to be made by the predictor 130. Using design of experiments, pairwise testing, Bayesian inference or the like, the processing condition determiner 120 selects one of a plurality of variable conditions that are prepared in advance and one of a plurality of fixed conditions that are prepared in advance, and determines a processing condition including a selected variable condition and a selected fixed condition as a new processing condition for prediction to be made by the predictor 130.

The processing condition determiner 120 may search for a processing condition using Bayesian inference. In a case in which a plurality of evaluation results are output by the evaluator 140, a plurality of sets each of which includes a processing condition and an evaluation result are obtained. Based on the likelihood of a prediction processing result for each of the plurality of sets, a processing condition that causes the film thickness to be uniform, or a processing condition that causes the difference between a film-thickness characteristic predicted to be obtained after the etching process and a target film-thickness characteristic to be minimum, is searched.

Specifically, the processing condition determiner 120 searches for a processing condition that causes an objective function to be minimized. The objective function is a function representing uniformity of film thickness or a function representing the consistency between a film-thickness characteristic and a target film-thickness characteristic. For example, the objective function represents, using a parameter, the difference between a film-thickness characteristic predicted to be obtained after the etching process and a target film-thickness characteristic. The parameter here is a corresponding variable condition. The corresponding variable condition is used for prediction of a prediction processing result by a prediction device. The processing condition determiner 120 selects a variable condition which is a parameter determined by search among a plurality of variable conditions, and determines a new processing condition including the selected variable condition and a fixed condition.

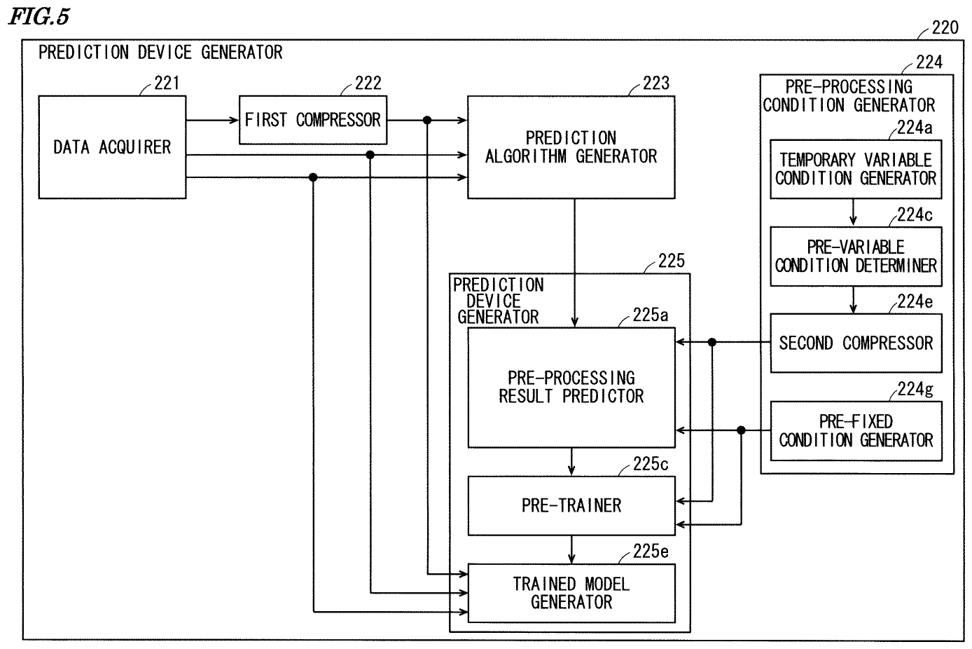

Next, details of the configuration of the prediction device generator 220 will be described below. FIG. 5 is a diagram showing one example of the functions of the prediction device generator. The prediction device generator 220 includes a data acquirer 221, a first compressor 222, a prediction algorithm generator 223, a pre-processing condition generator 224 and a prediction device generator 225.

The data acquirer 221 receives experimental data from the experimental data acquirer 210. The experimental data includes a processing condition and a processing result. The processing condition includes a fixed condition that does not vary over time and a variable condition that varies over time. The data acquirer 221 outputs the variable condition to the first compressor 222, and outputs the fixed condition and the processing result to the prediction algorithm generator 223. The first compressor 222 compresses the variable condition received from the data acquirer 221, and outputs the compressed data in which the variable condition is compressed to the prediction algorithm generator 223. Hereinafter, a set of the fixed condition, the processing result and the compressed data is referred to as a first dataset.

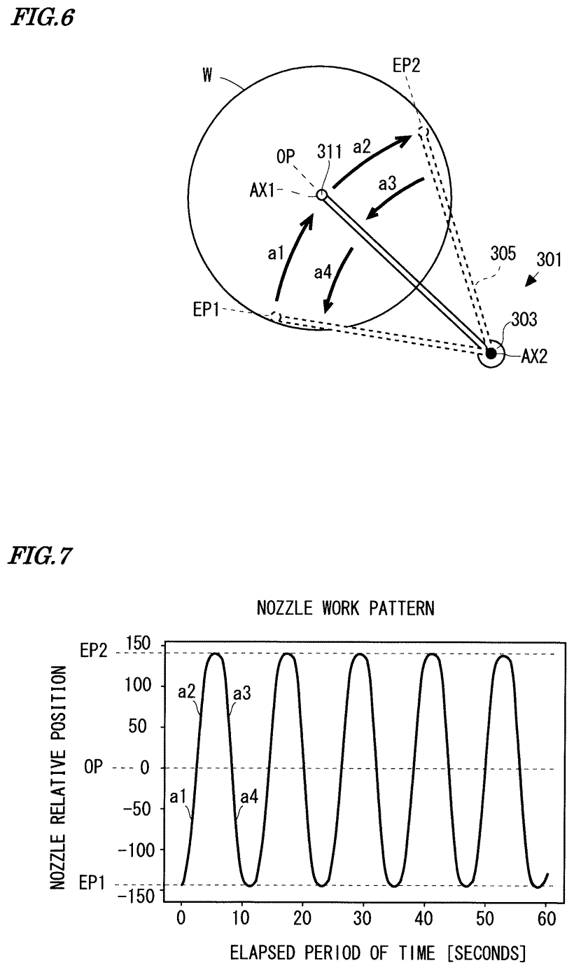

Here, a variable condition will be described. FIG. 6 is a diagram for explaining the change of a relative position of the nozzle with respect to the substrate in a film process. With reference to FIG. 6, the change of the relative position of the nozzle 311 with respect to the substrate W held by the spin chuck SC is shown. The nozzle 311 moves in the area above the substrate W held by the spin chuck SC. Because the nozzle 311 rotates about the second rotation axis AX2, the trajectory on which the nozzle 311 moves forms an arc. The trajectory on which the nozzle 311 moves passes through a substrate center OP, which is the center of the substrate. Therefore, the nozzle 311 moves from the substrate center OP to the entire peripheral portion in the radial direction of the substrate W. Here, in regard to the trajectory on which the nozzle 311 moves, its one end is indicated by a work end portion EP1 located farther inward than the peripheral portion of the substrate W, and the other end is indicated by a work end portion EP2 located farther inward than the peripheral portion of the substrate W. The scan in which the nozzle 311 moves from the work end portion EP1 to the substrate center OP is indicated by an arrow a1, the scan in which the nozzle 311 moves from the substrate center OP to the work end portion EP2 is indicated by an arrow a2, the scan in which the nozzle 311 moves from the work end portion EP2 to the substrate center OP is indicated by an arrow a3, and the scan in which the nozzle 311 moves from the substrate center OP to the work end portion EP1 is indicated by an arrow a4.

FIG. 7 is a diagram showing one example of a nozzle work pattern. In FIG. 7, the ordinate indicates a relative position of the nozzle 311 with respect to the substrate W, and the abscissa indicates an elapsed period of time (seconds). In the present embodiment, a scanning period from the start to the end of the nozzle work for moving the nozzle 311 with respect to the substrate W is equal to a processing period of time. As described above, because the processing period of time is set to sixty seconds, the nozzle work pattern is represented using the relative positions in the period of zero to sixty seconds. In regard to the relative position of the nozzle, the position of the substrate center OP is set to zero, a position in the range from the substrate center OP to the work end portion EP1 is indicated by a negative value, and a position in the range from the substrate center OP to the work end portion EP2 is indicated by a positive value. Because the substrate W has the radius of 300 mm, the distances from the substrate center OP to the work end portions EP1, EP2 are set to be equal to or smaller than +150 mm. Here, the distance from the substrate center OP to the work end portion EP1 is set to −147 mm, and the distance from the substrate center OP to the work end portion EP2 is set to +147 mm. In the nozzle work pattern of FIG. 7, the relative position of the nozzle 311 in a case in which the nozzle 311 is located at the substrate center OP is indicated by zero, the relative position of the nozzle 311 in a case in which the nozzle 311 is located at the work end portion EP1 is indicated by −147 mm, and the relative position of the nozzle 311 in a case in which the nozzle 311 is located at the work end portion EP2 is indicated by 147 mm.

The nozzle work pattern shown in FIG. 7 is shown as the scan in which the nozzle 311 reciprocates between the work end portion EP1 and the work end portion EP2 five times. A nozzle work pattern of the nozzle 311 of the substrate processing device 300 is not limited to the scan in which the nozzle 311 reciprocates five times. The nozzle 311 is only required to reciprocate once in the scan. In regard to the scan of the first reciprocation in the nozzle work pattern, the same reference numerals as the reference numerals of the arrows a1 to a4 in FIG. 6 are provided to the portions in FIG. 6 corresponding to the scans shown in FIG. 6.

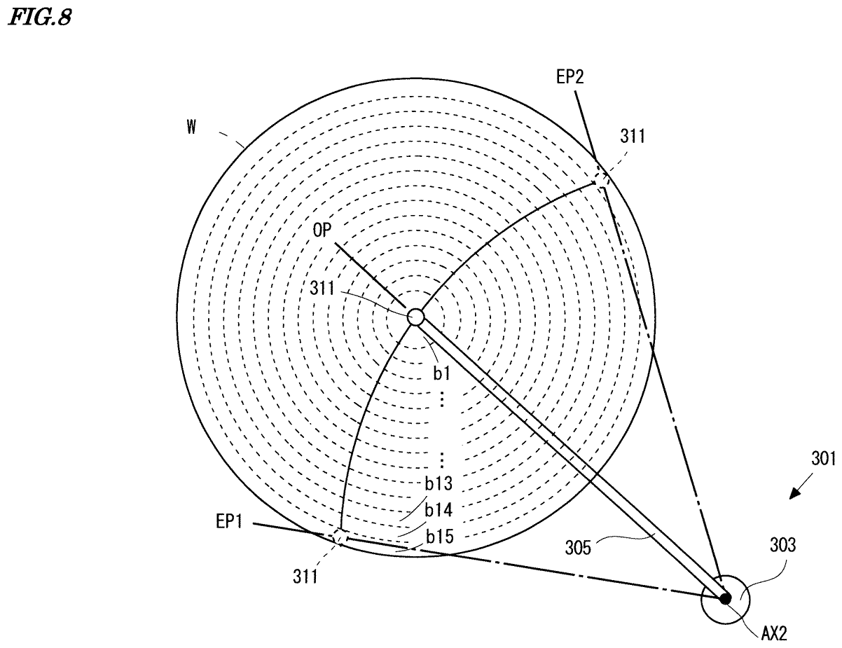

Here, compression of a variable condition will be described. In the present embodiment, the upper surface of the substrate W is divided into a plurality of divided areas for compression of a variable condition including a nozzle work pattern. FIG. 8 is a diagram for explaining divided areas. With reference to FIG. 8, the fifteen divided areas b1 to b15 obtained when the upper surface of the substrate W is divided by a plurality of concentric circles centered at the substrate center OP are shown. The divided area b1 is a circle, and the divided areas b2 to b15 are rings. The lengths of the plurality of divided areas b2 to b15 in the radial direction of the substrate W are the same. The length of each of the divided areas b2 to b15 in the radial direction of the substrate is the difference between the radius of the outer periphery and the radius of the inner periphery. The radius of the divided area b1 is equal to the length of each of the plurality of divided areas b2 to b15 in the radial direction of the substrate W. Here, the radius of the divided area b1 is 10 mm, and the difference between the radius of the outer periphery and the radius of the inner periphery of each of the divided areas b2 to b15 is 10 mm. The difference between the radii of the outer and inner peripheries of each of the divided areas b2 to b15 and the radius of the divided area b1 are larger than the inner diameter of the nozzle 311. The length of each of the divided areas b2 to b15 in the radial direction of the substrate and the radius of the divided area b1 are preferably equal to or larger than the inner diameter of the nozzle 311.

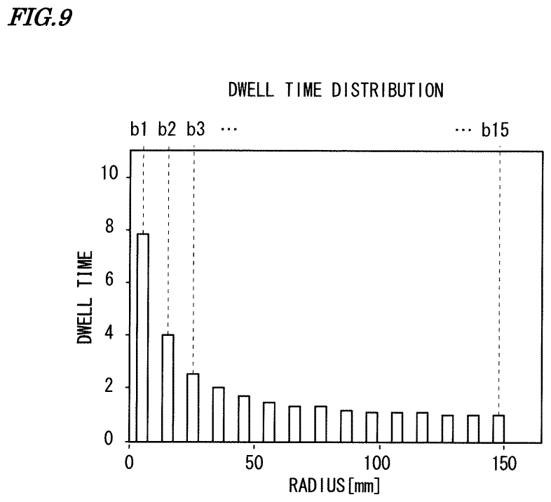

FIG. 9 is a diagram for explaining compression of a variable condition. In FIG. 9, the abscissa indicates a position in a radial direction of the substrate W. The position of the substrate center OP is indicated by 0 mm, and an end portion in the radial direction of the substrate W is indicated by 150 mm. The divided areas b1 to b15 are allocated between 0 mm and 150 mm of the ordinate.

The ordinate represents the dwell time during which the nozzle 311 dwells in each of the divided areas d1 to d15. Here, the dwell time during which the nozzle 311 dwells in each of the divided areas b1 to b15 in a case in which the nozzle 311 moves according to the work pattern shown in FIG. 7 is shown. The dwell time is the total period of time during which the nozzle 311 is located in each of the plurality of divided areas b1 to b15. For example, in a case in which the nozzle 311 moves according to the nozzle work pattern shown in FIG. 7, the nozzle 311 crosses the divided area b2 ten times. The dwell time in regard to the divided area b2 is the total period of time during which the nozzle 311 crosses the divided area b2.

As described above, the movement range of the nozzle 311 is divided into the plurality of divided areas b1 to b15. Therefore, the dwell time of the nozzle 311 in each of the plurality of divided areas b1 to b15 is calculated for each of the plurality of divided areas b1 to b15 including the information in regard to the position in the radial position of the substrate W. Therefore, the dwell time during which the nozzle 311 dwells in each of the plurality of divided areas b1 to b15 is the information including the position in the radial direction of the substrate W. Further, the lengths, in the radial direction of the substrate W, of the portions of the plurality of divided areas b1 to b15, which the nozzle 311 crosses are the same. Therefore, the dwell time during which the nozzle 311 dwells in each of the plurality of divided areas b1 to b15 can be set as a period of time with no bias in regard to the different positions in the radial direction of the substrate Was for the change of the relative position of the nozzle 311 with respect to the substrate.

Further, in the present embodiment, a variable condition is compressed by conversion of the variable condition into the dwell time of the nozzle in each of the divided areas b1 to b15, with the divided areas being obtained by division of the upper surface of the substrate W into fifteen areas. Hereinafter, a compressed variable condition is referred to as compressed data. The upper surface of the substrate Wis divided into the fifteen divided areas b1 to b15, and the number of compressed data pieces is fifteen. The larger the length of each of the divided areas b1 to b15 in the radial direction of the substrate, the smaller the number of compressed data pieces. The length of each of the divided areas b1 to b15 in the radial direction of the substrate is equal to or larger than the inner diameter of the nozzle 311. Therefore, the maximum value of the number of compressed data pieces is defined based on the inner diameter of the nozzle 311.

With reference back to FIG. 5, the prediction algorithm generator 223 receives a fixed condition and a processing result output from the data acquirer 221, and compressed data output from the first compressor 222. Here, a first dataset includes the fixed condition and the processing result output from the data acquirer 221 and the compressed data output from the first compressor 222. In the present embodiment, the prediction algorithm generator 223 generates a prediction algorithm based on the first dataset. Specifically, the prediction algorithm generator 223 causes a model constructed based on an algorithm of machine learning to execute machine learning using the first dataset, and generates a trained model as a prediction algorithm. For example, the prediction algorithm generator 223 provides the fixed condition and the compressed data included in the first dataset to the prediction algorithm, and adjusts a parameter of the prediction algorithm such that a prediction processing result to be predicted by the prediction algorithm is close to the processing result included in the first dataset. The prediction algorithm generator 223 outputs the prediction algorithm to the prediction device generator 225. Details of the prediction algorithm will be described below.

The pre-processing condition generator 224 generates a pre-processing condition, and outputs the generated pre-processing condition to the prediction device generator 225. The pre-processing condition includes a pre-variable condition and a pre-fixed condition. Specifically, the pre-processing condition generator 224 includes a temporary variable condition generator 224a, a pre-variable condition determiner 224c, a second compressor 224e and a pre-fixed condition generator 224g. The temporary variable condition generator 224a generates a plurality of temporary variable conditions.

A plurality of temporary variable conditions generated by the temporary variable condition generator 224a have different combinations of factors relating to a nozzle work such as a reciprocation count of the nozzle 311, a moving velocity of the nozzle 311 and a shift point during movement of the nozzle 311 in the film process. In the present embodiment, the number of temporary variable conditions generated by the temporary variable condition generator 224a is 18,000. The temporary variable condition generator 224a outputs the plurality of generated temporary variable conditions to the pre-variable condition determiner 224c.

The pre-variable condition determiner 224c determines a plurality of pre-variable conditions from among the plurality of temporary variable conditions. The pre-variable condition determiner 224c determines 960 temporary variable conditions as pre-variable conditions, for example. The pre-variable condition determiner 224c determines randomly selected temporary variable conditions as pre-variable conditions, for example.

With reference back to FIG. 5, the pre-variable condition determiner 224c outputs the plurality of pre-variable conditions to the second compressor 224e. The second compressor 224e compresses the plurality of respective pre-variable conditions and outputs a plurality of compressed data pieces to the prediction device generator 225. Compression of a pre-variable condition by the second compressor 224e is the same as compression of a variable condition by the first compressor 222. Therefore, the description thereof will not be repeated here.

The pre-fixed condition generator 224g determines any fixed condition as a pre-fixed condition, and outputs the pre-fixed condition to the prediction device generator 225. In the present embodiment, nine temporary fixed conditions, which are combinations of three rotation speeds of the substrate and three flow rates of the etching liquid, are determined as pre-fixed conditions.

Here, a pre-processing condition includes a pre-variable condition (compressed data) compressed by the second compressor 224e and a pre-fixed condition determined by the pre-fixed condition generator 224g. As described above, there are a plurality of compressed data pieces in which the pre-variable conditions are compressed, and a plurality of pre-fixed conditions. A pre-processing condition is a set of one of the plurality of compressed data pieces and one of the plurality of pre-fixed conditions. Therefore, pre-processing conditions the number of which is equal to the number of combinations of one of a plurality of compressed data pieces and one of a plurality of pre-fixed conditions are output to the prediction device generator 225. In the present embodiment, the nine hundred sixty compressed data pieces obtained by compression of the pre-variable conditions by the second compressor 224e and the nine pre-fixed conditions determined by the pre-fixed condition generator 224g form 8,640 datasets. The eight thousand six hundred forty datasets are combined into 2,716 datasets by pairwise testing. The two thousand seven hundred sixteen datasets are output to the prediction device generator 225 as pre-processing conditions.

The prediction device generator 225 includes a pre-processing result predictor 225a, a pre-trainer 225c and a learning model generator 225e. The pre-processing result predictor 225a receives the prediction algorithm output from the prediction algorithm generator 223, the compressed data output from the second compressor 224e, and the pre-fixed condition output from the pre-fixed condition generator 224g. The pre-processing result predictor 225a predicts a pre-processing result based on the pre-processing conditions using the prediction algorithm. A pre-processing condition includes a compressed data piece received from the second compressor 224e and a pre-fixed condition received from the pre-fixed condition generator 224g. Specifically, the pre-processing result predictor 225a inputs the pre-processing conditions to the prediction algorithm, and acquires the processing result predicted by the prediction algorithm as a pre-processing result. The pre-processing result predictor 225a outputs the pre-processing result to the pre-trainer 225c.

The pre-trainer 225c receives the compressed data output from the second compressor 224e, the pre-fixed condition output from the pre-fixed condition generator 224g, and the pre-processing result output from the pre-processing result predictor 225a. A set of a compressed data piece received from the second compressor 224e and a pre-fixed condition received from the pre-fixed condition generator 224g is a pre-processing condition. Hereinafter, a set of a pre-processing condition and a pre-processing result that are input to the pre-trainer 225c is referred to as a second dataset. The pre-processing result included in the second dataset is a pre-processing result obtained when the pre-processing result predictor 225a causes the prediction algorithm to make a prediction based on the pre-processing condition included in the second dataset.

The pre-trainer 225c causes a learning model to execute machine learning using the second dataset. Specifically, the pre-trainer 225c provides the pre-processing condition included in the second dataset to the learning model, and adjusts a parameter of the learning model such that a prediction processing result predicted by the learning model is brought closer to the pre-processing result included in the second dataset. In the present embodiment, with an initial value being set, the learning model which is made to execute machine learning by the pre-trainer 225c is the same as a prediction algorithm in which an initial value is set. Due to pre-training by the pre-trainer 225c, the learning model can execute machine learning using a plurality of variable conditions having a plurality of characteristics as pre-knowledge with no bias in regard to any of the plurality of characteristics. Hereinafter, machine learning to be executed in the pre-trainer 225c is referred to as pre-training. The pre-trainer 225c outputs a pre-trained learning model to the learning model generator 225e.

The learning model generator 225e receives a fixed condition and a processing result output from the data acquirer 221 and compressed data output from the first compressor 222. Here, a set of the fixed condition and the processing result output from the data acquirer 221 and the compressed data output from the first compressor 222 is the first dataset. Further, the learning model generator 225e receives the pre-trained learning model output from the pre-trainer 225c. The learning model generator 225e causes the pre-trained learning model to further execute machine learning using the first dataset.

A learning model that is made to execute machine learning by the learning model generator 225e is the pre-trained learning model that has been pre-trained by the pre-trainer 225c. Because the pre-trained learning model has been trained using a plurality of characteristics of a variable condition, it is possible to reduce the influence of bias in regard to characteristics of the variable condition included in experimental data in machine learning using the experimental data by the learning model generator 225e, and improve prediction accuracy.

The learning model generator 225e sets a combination of a learning model that has been trained using the second dataset and a compression device as a prediction device, and outputs the prediction device to the prediction device transmitter 230. The function of the compression device included in the prediction device is similar to the function of the first compressor 222.

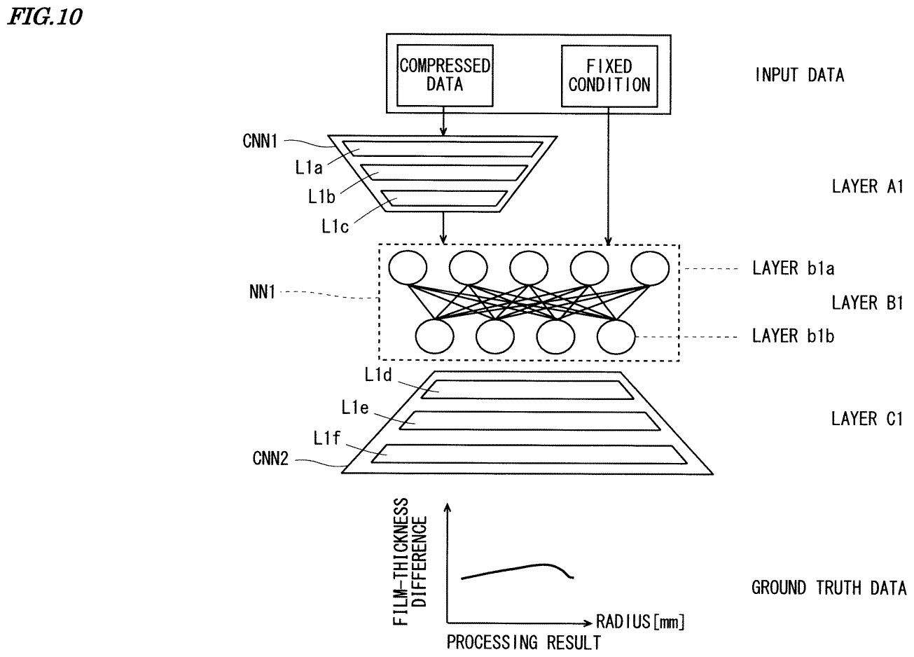

Here, a prediction algorithm according to the present embodiment will be described. FIG. 10 is a diagram for explaining a prediction algorithm. With reference to FIG. 10, in the prediction algorithm, layers A1 to C1 are provided in this order from the input side to the output side (from the upper layer to the lower layer). A first convolutional neural network CNN1 is provided in the layer A1, a first fully-connected neural network NN1 is provided in the layer B1, and a second convolutional neural network CNN2 is provided in the layer C1.

The compressed data representing a compressed variable condition is input to the first convolutional neural network CNN1. The output of the first convolutional neural network CNN1 and a fixed condition are input to the first fully-connected neural network NN1. The output of the first fully-connected neural network NN1 is input to the second convolutional neural network CNN2.

The first convolutional neural network CNN1 includes a plurality of layers. In the present embodiment, the first convolutional neural network CNN1 includes three layers. In the first convolutional neural network CNN1, a first layer L1a, a second layer L1b and a third layer L1c are provided in this order from the input side (upper layer side) to the output side (lower layer side). While the three layers are included as a plurality of layers in the description in the present embodiment, three or more layers may be included.

Each of the first layer L1a, the second layer L1b and the third layer L1c includes a convolution layer and a pooling layer. In the convolution layer, a plurality of filters are used. The pooling layer compresses the output of the convolution layer. The number of filters of the convolution layer of the second layer L1b is set to twice of the number of filters of the convolution layer of the first layer L1a. The number of filters of the convolution layer of the third layer L1c is set to twice of the number of filters of the convolution layer of the second layer L1b. Therefore, it is possible to extract as many features as possible from the compressed data. Here, the variable condition that is the source of the compressed data includes a relative position of the nozzle with respect to the substrate W, with the relative position varying over time. The first convolutional neural network CNN1 extracts the features using the plurality of filters, thereby extracting a plurality of features including time elements in regard to the change in relative position of the nozzle with respect to the substrate W. While being set to twice of the number of filters of the convolution layer of the first layer L1a here by way of example, the number of filters of the convolution layer of the second layer L1b does not have to be twice of the number of filters of the convolution layer of the first layer L1a. The number of filters of the convolution layer of the second layer L1b is only required to be larger than the number of filters of the convolution layer of the first layer L1a. Further, the number of filters of the convolution layer of the third layer L1c does not have to be twice of the number of filters of the convolution layer of the second layer L1b. The number of filters of the convolution layer of the third layer L1c is only required to be larger than the number of filters of the convolution layer of the second layer L1b.

The first fully-connected neural network NN1 includes a plurality of layers. In the example of FIG. 10, the first fully-connected neural network NN1 includes two layers, which are, a layer b1a on the input side and a layer b1b on the output side. In the example of FIG. 10, each layer includes a plurality of nodes. While five nodes are shown in the layer b1a and four nodes are shown in the layer b1b in the example of FIG. 10, the number of nodes is not limited to these. The number of nodes of the layer b1a is set equal to the sum of the number of nodes on the output side of the first convolutional neural network CNN1 and the number of fixed conditions. The number of nodes of the layer b1b is set equal to the number of nodes on the input side of the second convolutional neural network CNN2. The output of a node of the layer b1a is connected to the input of a node of the layer b1b. A parameter includes a coefficient for weighting the output of a node of the layer b1a. One or a plurality of intermediate layers may be provided between the layer b1a and the layer b1b.

The second convolutional neural network CNN2 includes a plurality of layers. In the present embodiment, the second convolutional neural network CNN2 includes three layers. In the second convolutional neural network CNN2, a fourth layer L1d, a fifth layer L1e and a sixth layer L1f are provided in this order from the input side (upper layer side) to the output side (lower layer side). While the three layers are included as a plurality of layers in the description in the present embodiment, three or more layers may be included.

Each of the fourth layer L1d, the fifth layer L1e and the sixth layer L1f includes a convolution layer and a pooling layer. In the convolution layer, a plurality of filters are used. The pooling layer compresses the output of the convolution layer. The number of filters of the convolution layer of the fifth layer L1e is set to one-half of the number of filters of the convolution layer of the fourth layer L1d. Further, the number of filters of the convolution layer of the sixth layer L1f is set to one-half of the number of filters of the convolution layer of the fifth layer L1e. Therefore, it is possible to extract as many features as possible from the processing result. A plurality of processing amounts included in the processing result are values obtained at different positions in the radial direction of the substrate W. The second convolutional neural network CNN2 uses the plurality of filters, thereby extracting a plurality of features including elements of the position in the radial direction of the substrate W in regard to the processing result. While being set to one-half of the number of filters of the convolution layer of the fourth layer L1d here by way of example, the number of filters of the convolution layer of the fifth layer L1e does not have to be one-half of the number of filters of the convolution layer of the fourth layer L1d. The number of filters of the convolution layer of the fifth layer L1e is only required to be smaller than the number of filters of the convolution layer of the fourth layer L1d. Further, the number of filters of the convolution layer of the sixth layer L1f does not have to be one-half of the number of filters of the convolution layer of the fifth layer L1e. The number of filters of the convolution layer of the sixth layer L1f is only required to be smaller than the number of filters of the convolution layer of the fifth layer L1e.

The configuration of a learning model is similar to the configuration of a prediction algorithm. In other words, a prediction algorithm in which an initial value is set and a learning model in which an initial value is set are similar to each other. Note that training data used in machine learning of a prediction algorithm includes a fixed condition, a processing result, and compressed data in which a variable condition is compressed. However, training data used in machine learning of a learning model includes a pre-fixed condition, a pre-processing result and compressed data in which a pre-variable condition is compressed.

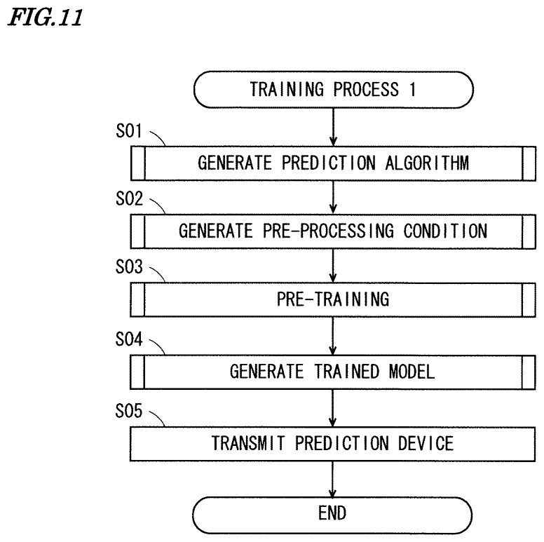

FIG. 11 is a flowchart showing one example of a flow of a training process. The training process is a process executed by the CPU 201 included in the training device 200 when the CPU 201 executes a training program stored in the RAM 202.

With reference to FIG. 11, the CPU 201 included in the training device 200 executes a prediction algorithm generation process (step S01). Subsequently, the CPU 201 executes a pre-processing condition generation process of generating a pre-processing condition for execution of pre-training (step S02). In the next step S03, the CPU 201 executes pre-training on a learning model using a prediction algorithm generated in the step S01 and a pre-processing condition generated in the step S02. In the next step S04, the CPU 201 executes a learning model generation process of executing machine learning on the pre-trained learning model. In the step S05, the CPU 201 generates a prediction device including a learning model and a compression device, and transmits the prediction device to the information processing apparatus 100 by controlling the input-output I/F 207.

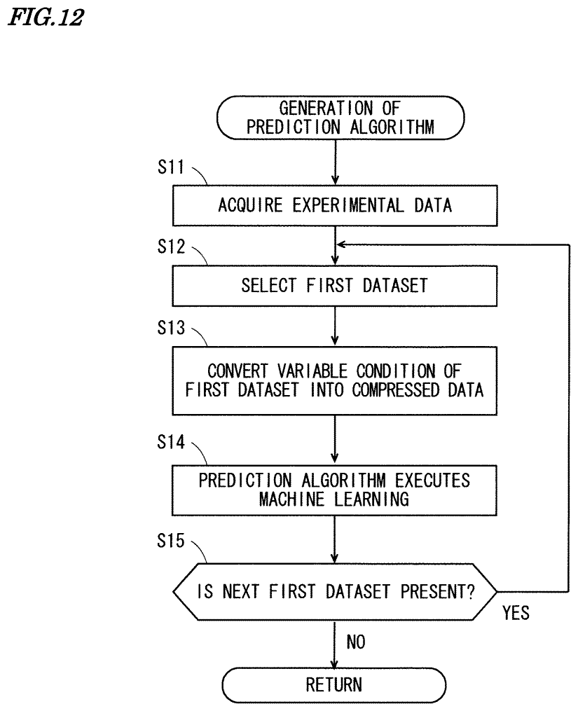

FIG. 12 is a flowchart showing one example of a flow of the prediction device generation process. The prediction algorithm generation process is executed by the CPU 201 in the step S01 of FIG. 11.

With reference to FIG. 12, the CPU 201 included in the training device 200 acquires experimental data (step S11). The CPU 201 controls the input-output I/F 107 to acquire the experimental data from the substrate processing device 300. The experimental data may be acquired when the experimental data recorded in a recording medium such as the CD-ROM 209 is read by the storage device 104. A plurality of experimental data pieces are acquired here. The experimental data includes a plurality of first datasets. The first dataset includes a processing condition, and a processing result of a film process executed in the substrate processing device 300 according to the processing condition. The processing condition includes a variable condition and a fixed condition.

In the step S12, the CPU 201 selects one first dataset as data to be processed. In the next step S13, the CPU 201 converts a variable condition included in a processing condition of the selected first dataset into compressed data. Here, the CPU 201 converts the variable condition including a nozzle work pattern into the nozzle dwell time distribution shown in FIG. 9. In the step S14, the CPU 201 causes a prediction algorithm to execute machine learning using a fixed condition of the selected first dataset, the compressed data obtained when the variable condition is converted, and a processing result. In the machine learning with respect to the prediction algorithm, the fixed condition of the first dataset selected as data to be processed, and the compressed data obtained when the variable condition is converted, are used as input data, and the processing result of the selected first dataset is used as ground truth data.

In the step S15, the CPU 201 determines whether an unselected first dataset is present. In a case in which an unselected first dataset is present, the process returns to the step S12. In a case in which no unselected first dataset is present, the process returns to the training process.

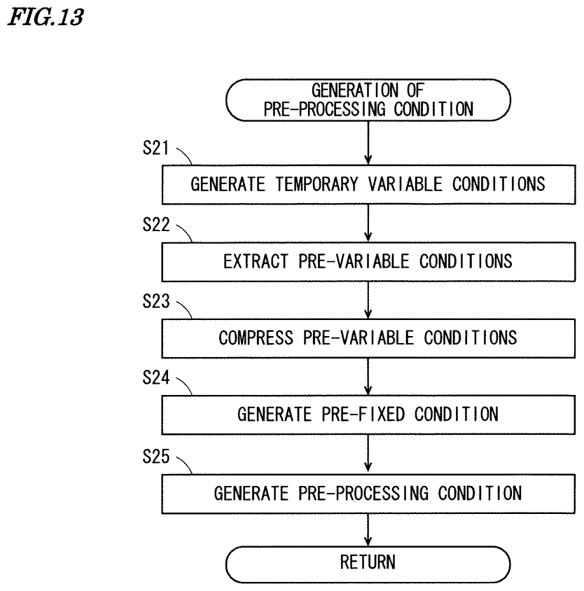

FIG. 13 is a flowchart showing one example of a flow of the pre-processing condition generation process. The pre-processing condition generation process is executed by the CPU 201 in the step S02 of FIG. 11.

With reference to FIG. 13, the CPU 201 included in the training device 200 generates a temporary variable condition (step S21). The temporary variable condition includes a reciprocation count of the nozzle 311, a moving velocity of the nozzle 311, and a shift point during movement of the nozzle 311, in the film process. Here, a plurality of temporary variable conditions having different combinations of factors relating to the nozzle work such as a reciprocation count of the nozzle 311, a moving velocity of the nozzle 311, and a shift point during movement of the nozzle 311, in the film process, are generated.

In the next step S22, the CPU 201 extracts a predetermined number of pre-variable conditions from the plurality of generated temporary variable conditions.

In the next step S23, the CPU 201 compresses the extracted pre-variable conditions. Here, the CPU 201 compresses the pre-variable conditions by converting the pre-variable conditions into the nozzle dwell time distribution shown in FIG. 9. In the step S24, the CPU 201 determines any fixed condition as a pre-fixed condition. Here, fixed conditions having different substrate rotation speeds and different flow rates of the etching liquid are determined as a plurality of pre-fixed conditions. In the step S25, the CPU 201 generates, as pre-processing conditions, using pairwise testing, a plurality of datasets each of which includes compressed data obtained when a pre-variable condition is extracted in the step S22 and compressed in the step S23, and a pre-fixed condition determined in the step S24.

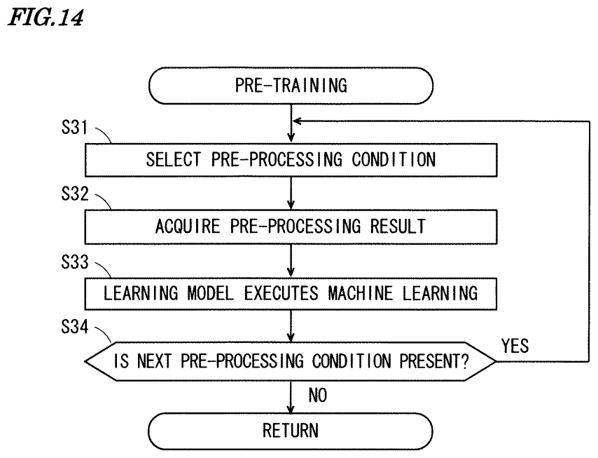

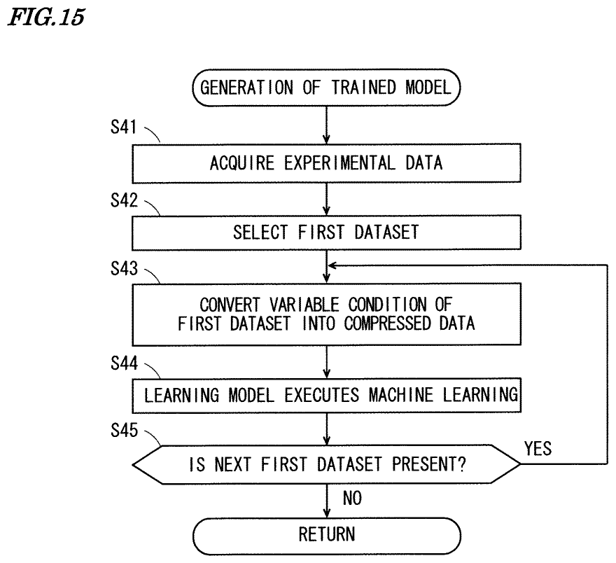

FIG. 14 is a flowchart showing one example of a flow of a pre-training process. The pre-training process is executed by the CPU 201 in the step S03 of FIG. 11.

With reference to FIG. 14, the CPU 201 included in the training device 200 selects one pre-processing condition from among the plurality of pre-processing conditions generated by execution of the pre-processing condition generation process (step S31). In the step S32, the CPU 201 acquires a pre-processing result using the prediction algorithm generated by execution of the prediction algorithm generation process and the selected pre-processing condition. Here, a processing result is predicted by input of the pre-processing condition to the prediction algorithm, and the predicted processing result is acquired as the pre-processing result. At this stage, a set of the pre-processing condition and the pre-processing result is generated as a second dataset.

In the next step S33, a learning model executes machine learning using the second dataset. The second dataset includes the pre-processing condition selected in the step S31 and the pre-processing result acquired in the step S32. In regard to machine learning with respect to the learning model, the pre-processing condition is used as input data, and the pre-processing result is used as ground truth data. In the step S34, the CPU 201 determines whether an unselected pre-processing condition is present. In a case in which an unselected pre-processing condition is present, the process returns to the step S31. In a case in which no un-selected preprocessing condition is present, the process returns to the training process. Thus, a pre-trained learning model is generated.

FIG. 15 is a flowchart showing one example of a flow of the learning model generation process. The learning model generation process is executed by the CPU 201 in the step S04 of FIG. 11.

With reference to FIG. 15, the CPU 201 included in the training device 200 acquires experimental data. The CPU 201 controls the input-output I/F 107 to acquire the experimental data from the substrate processing device 300 (step S41). The experimental data may be acquired when the experimental data recorded in a recording medium such as the CD-ROM 209 is read by the storage device 104. The experimental data acquired here is the same as the experimental data used when the prediction algorithm is generated. Therefore, the number of experimental data pieces can be reduced as much as possible.

The experimental data includes a plurality of first datasets. The first dataset includes a processing condition, and a processing result of the film process executed in the substrate processing device 300 according to the processing condition. The processing condition includes a variable condition and a fixed condition. In the step S42, the CPU 201 selects one first dataset. In the next step S43, the CPU 201 converts the variable condition included in the processing condition of the selected first dataset into compressed data. Here, the CPU 201 converts the variable condition including a nozzle work pattern into the nozzle dwell time distribution shown in FIG. 9. In the step S44, the CPU 201 causes the pre-trained learning model to execute machine learning using a fixed condition of the selected first dataset, the compressed data obtained when the variable condition is converted, and a processing result. In the machine learning with respect to the pre-trained learning model, the fixed condition of the first dataset selected in the step S42, and the compressed data obtained when the variable condition of the first data set is converted, are used as input data, and the processing result of the first dataset selected in the step S42 is used as ground truth data.

In the step S45, the CPU 201 determines whether an unselected first dataset is present. In a case in which an unselected first dataset is present, the process returns to the step S42. In a case in which no unselected first dataset is present, the process returns to the training process.

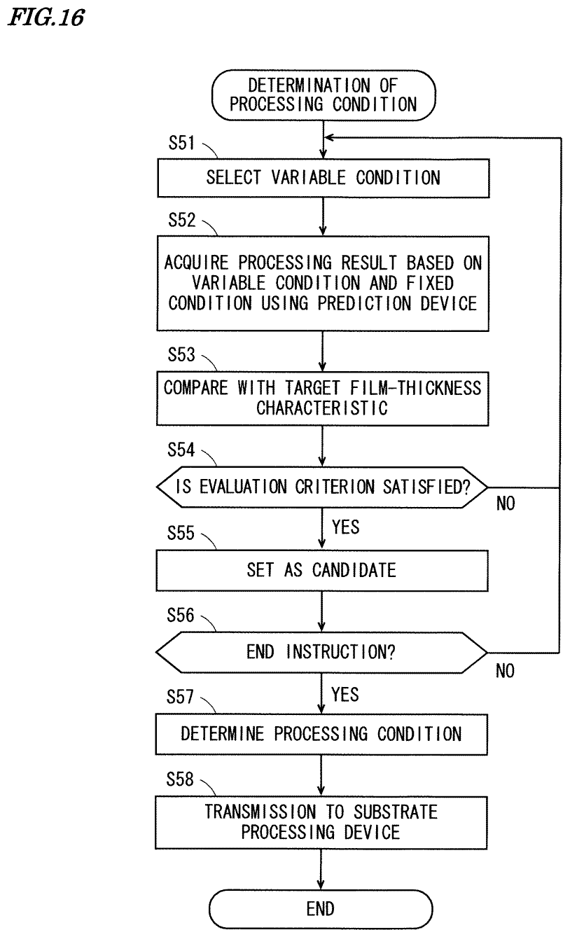

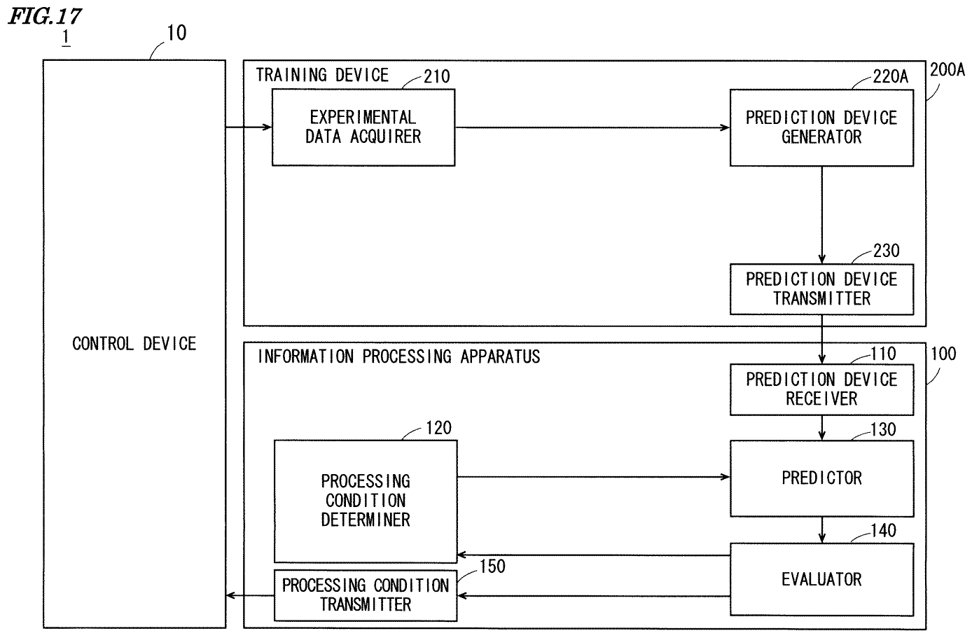

FIG. 16 is a flowchart showing one example of a flow of a processing condition determination process. The processing condition determination process is executed by the CPU 101 included in the information processing apparatus 100 when the CPU 101 executes the processing condition determination program stored in the RAM 102.

With reference to FIG. 16, the CPU 101 included in the information processing apparatus 100 selects one of a plurality of variable conditions that are prepared in advance (step S51), and the process proceeds to the step S52. Using design of experiments method, pairwise testing, Bayesian inference or the like, one of the plurality of variable conditions prepared in advance is selected.

In the step S52, a processing result is predicted based on the variable condition and a fixed condition using a prediction device, and the process proceeds to the step S53. Here, the variable condition is input to a compression device of the prediction device, and compressed data is output from the compression device. A learning model of the prediction device receives the compressed data and the fixed condition. Thus, the processing result output by the learning model is acquired. In the step S53, a film-thickness characteristic obtained after a process is compared with a target film-thickness characteristic. Based on a film-thickness characteristic obtained before a process for the substrate W to be processed by the substrate processing device 300 and an etching profile predicted in the step S52, the film-thickness characteristic to be obtained after the substrate W is processed is calculated. Then, the film-thickness characteristic obtained after the process is compared with the target film-thickness characteristic. Here, the difference between the film-thickness characteristic obtained after the substrate W is processed and the target film-thickness characteristic is calculated.

In the step S54, whether a comparison result satisfies an evaluation criterion is determined. If the comparison result satisfies the evaluation criterion (YES in the step S54), the process proceeds to the step S55. If not, the process returns to the step S51. For example, in a case in which the maximum value of difference is equal to or smaller than a threshold value, it is determined that the evaluation criterion is satisfied. Further, in a case in which the average value of difference is equal to or smaller than the threshold value, it is determined that the evaluation criterion is satisfied.

In the step S55, the processing condition including the variable condition selected in the step S51 is set as a candidate processing condition for driving the substrate processing device 300, and the process proceeds to the step S56. In the step S56, whether an instruction for ending the search has been accepted is determined. If an end instruction provided by the user who operates the information processing apparatus 100 is accepted, the process proceeds to the step S57. If not, the process returns to the step S51. Instead of the end instruction input by the user, whether a predetermined number of processing conditions have been set as candidates may be determined.

In the step S57, one of one or more processing conditions set as candidates is selected, and the process proceeds to the step S58. One of one or more processing conditions set as candidates may be selected by the user who operates the information processing apparatus 100. This widens the range of selection for the user. Further, a variable condition according to which the nozzle work can be performed most simply may be automatically selected from among variable conditions included in a plurality of processing conditions. The variable condition according to which the nozzle work is performed most simply can be a variable condition according to which the nozzle work is performed with the smallest number of shift points, for example. Thus, a plurality of variable conditions can be presented in regard to a processing result for the complicated nozzle work for processing the substrate W. When a variable condition according to which the nozzle is easily controlled is selected from among a plurality of variable conditions, the control of the substrate processing device 300 is facilitated.

In the step S58, the processing condition including the variable condition determined in the step S58 is transmitted to the substrate processing device 300, and the process ends. The CPU 101 controls the input-output I/F 107 and transmits the processing condition to the substrate processing device 300. In a case in which receiving the processing condition from the information processing apparatus 100, the substrate processing device 300 processes the substrate W according to the processing condition.

### (4) Modified Example

The training device 200 in the above-mentioned embodiment generates, as a second dataset to be learned by a learning model, a pre-processing condition and a prediction processing result separately from experimental data, using a prediction algorithm that has executed machine learning using experimental data. A training device 200A in a modified example generates a pre-processing condition and a prediction processing result as a second dataset to be learned by a learning model, using a rule-based prediction algorithm that performs an analysis in consideration of a physical quantity.

FIG. 17 is a diagram showing one example of the functional configuration of a substrate processing system in the modified example. With reference to FIG. 17, a difference from the functions shown in FIG. 4 is that the training device 200 is changed to the training device 200A. The other functions are the same as those shown in FIG. 4. A description thereof will therefore not be repeated. The training device 200A includes an experimental data acquirer 210, a prediction device generator 220A and a prediction device transmitter 230. The experimental data acquirer 210 and the prediction device transmitter 230 are the same as the functions shown in FIG. 4.

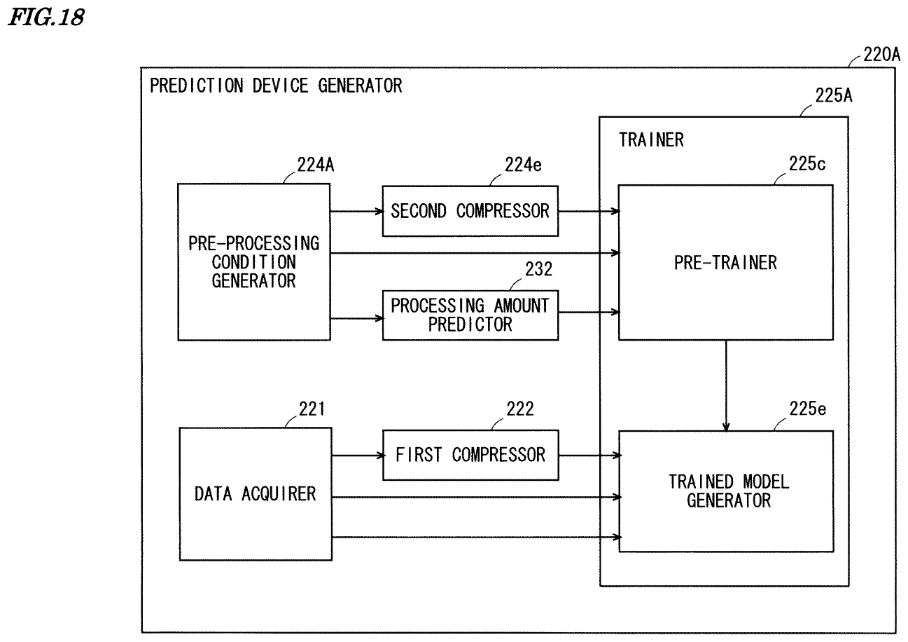

FIG. 18 is a diagram showing one example of the functions of a prediction device generator in the modified example. With reference to FIG. 18, the prediction device generator 220A in the modified example includes a data acquirer 221, a first compressor 222, a pre-processing condition generator 224A, a second compressor 224e, a processing amount predictor 232 and a trainer 225A.

The data acquirer 221 receives experimental data from the experimental data acquirer 210. The experimental data includes a processing condition and a processing result. The processing condition includes a fixed condition that does not vary over time, and a variable condition that varies over time. The data acquirer 221 outputs the variable condition to the first compressor 222, and outputs the fixed condition and the processing result to the trainer 225A. The first compressor 222 compresses the variable condition received from the data acquirer 221, and outputs compressed data in which the variable condition is compressed to the trainer 225A. A set of the fixed condition and the processing result output from the data acquirer 221, and the compressed data output from the first compressor 222 is a first dataset.

The pre-processing condition generator 224A generates a pre-processing condition. Detailed functions of the pre-processing condition generator 224A will be described below. The pre-processing condition includes a pre-variable condition and a pre-fixed condition. The pre-processing condition generator 224A outputs the generated pre-processing condition to the processing amount predictor 232. Further, the pre-processing condition generator 224A outputs the pre-variable condition of the pre-processing condition to the second compressor 224e, and outputs the pre-fixed condition to the trainer 225A. The second compressor 224e compresses the pre-variable condition received from the pre-processing condition generator 224A. The second compressor 224e outputs the compressed data in which the pre-variable condition is compressed to the trainer 225A.

The processing amount predictor 232 calculates a pre-processing result using a prediction algorithm determined in advance based on the pre-processing condition. The pre-processing result includes a processing amount at each of a plurality of positions of the substrate. The processing amount predictor 232 outputs the calculated pre-processing result to the trainer 225A. A set of the compressed data output from the first compressor 222, the pre-fixed condition output from the pre-processing condition generator 224A and the pre-processing result output from the processing amount predictor 232 is a second dataset.

Here, the prediction algorithm used by the processing amount predictor 232 for calculation of a processing amount will be described. The prediction algorithm is a model based on physical laws using CFD (computational fluid dynamics) simulation. Hereinafter, the prediction algorithm used by the processing amount predictor 232 is referred to as a CFD model.

Here, a film to be etched is silicon oxide (SiO₂), and a processing liquid is hydrofluoric acid (HF). A CFD model can also be applied to a case in which a film to be etched is (Al₂O₃) and the processing liquid is SC1 (ammonia peroxide solution). In short, the CFD model can be applied to a combination of a processing liquid equivalent to a reaction rate-limiting system and a film to be etched.

The CFD model includes a plurality of algorithms that simulate the behavior of the processing liquid spreading on the substrate W, various heat transfer, mass transfer in the processing liquid, and a reaction amount (etching amount) between the processing liquid and the substrate W, in a period during which the processing liquid is discharged to the substrate W from the nozzle 311 that reciprocates on the rotating substrate W. The algorithm for simulating heat transfer includes an algorithm for simulating heat transfer between the processing liquid and the substrate W, an algorithm for simulating heat transfer in the processing liquid, and an algorithm for simulating heat transfer in the substrate W.

Specifically, the CFD model includes the below-mentioned governing equations (1) to (4). The processing amount predictor 232 performs spatiotemporal discretization using the governing equations (1) to (4). Specifically, the processing amount predictor 232 calculates a film-thickness distribution of the processing liquid, a temperature distribution of the substrate W, and a processing amount (etching rate) of the film formed on the substrate W, at any point in time, by formulating the governing equations (1) to (4) and solving the time evolution.

$$\begin{matrix}[ Formulation 1 ] & \\ & ( Formulation 1 )\end{matrix}$$

$$\frac{\partial h}{\partial t} = - ∇ \cdot [ \frac{\partial {h}_{3}}{3 μ} \frac{\partial {}^{3} h}{\partial {x}^{3}} - \frac{ρ {gh}^{3}}{3 μ} \frac{\partial h}{\partial x} + \frac{ρ r {ω}^{2}}{3 {μ}^{2}} {h}^{3} ] + S ( x , t )$$

Here, t is a period of time [s], x is a spatial step size [mm], h is a film thickness [μm] of the processing liquid, r is a radial position [mm], and ω is a rotation speed [rpm] of the substrate W. Further, μ is a viscous coefficient of liquid, and ρ is a density of liquid [kg/m³].

$$\begin{matrix}[ Formulation 2 ] & \\ & ( Formulation 2 )\end{matrix}$$

$$ρ Cp ( \frac{\partial {T}_{liquid}}{\partial t} + u \frac{\partial {T}_{liquid}}{\partial x} ) = k \frac{\partial {}^{2} {T}_{liquid}}{\partial {x}^{2}} + \text{?} ( x , t ) + q 1 ( x \text{?} t ) - q 2 ( x , t )$$

$$\text{?} \text{indicates text missing or illegible when filed}$$

Here, Cp is the specific heat of the processing liquid, T_{liquid} is a temperature [K] of the processing liquid, T_{wafer} is a temperature [K] of the substrate W, and u is a flow velocity [m/s] of the processing liquid. K is a thermal conductivity of the processing liquid.

$$\begin{matrix}[ Formulation 3 ] & \\ ρ Cp ( \frac{\partial {T}_{wafer}}{\partial t} ) = k \frac{\partial {}_{}^{2} {T}_{wafer}^{}}{\partial {x}^{2}} + q 2 ( x , t ) & ( Formulation 3 )\end{matrix}$$

$$\begin{matrix}[ Formulation 4 ] & \\ ER = \frac{{M}_{wafer}}{{ρ}_{wafer}} \cdot A \cdot exp ( \frac{- Ea}{{RT}_{wafer}} ) \cdot {( C )}^{α} \text{?} & ( Formulation 4 )\end{matrix}$$

$$\text{?} \text{indicates text missing or illegible when filed}$$

Here, ER is an etching rate, M_{wafer} is a molecular weight of silicon oxide on the substrate, and ρ_{wafer} is a density of silicon oxide on the substrate. A and Ea are Arrhenius parameters, and C is a molar concentration of the processing liquid. α is 1.

S(x, t) in the governing equation (1) represents the influence entering the system from the outside. S(x, t) is obtained based on a flow rate of the processing liquid and its position. A position is obtained based on time-series data of the position of the nozzle 311. Further, because the right-hand side of the governing equation (1) includes S(x, t), the flow rate of the processing liquid to be discharged from the nozzle 311 moving on the substrate W is modeled as an inflow of the processing liquid into the system. By solution of the governing equation (1), the thickness of a liquid film of the processing liquid flowing on the rotating substrate W is calculated.

The governing equation (2) is an equation representing heat transfer inside of the processing liquid. Q(x, t) in the governing equation (2) represents the influence entering the system from the outside. Q(x, t) is obtained based on an inflow of temperature and its position. A temperature is obtained based on a temperature of the processing liquid, and a position is obtained based on time-series data of the position of the nozzle 311.

q1(x, t) represents an amount of heat that is generated in a liquid film of the processing liquid and a surrounding fluid. q2(x, t) represents an amount of heat that is exchanged between the liquid film of the processing liquid and the substrate W. q1(x, t) can be determined by heat transfer with a temperature of an atmosphere fixed at RT (room temperature), for example, and the following formulation (5) holds. In regard to q2(x, t), the following formulation (6) holds.

$$\begin{matrix}[ Formulation 5 ] & \\ q 1 ( x , t ) = h 1 ( {T}_{liquid} - {T}_{ref} ) & ( Formulation 5 )\end{matrix}$$

$$\begin{matrix} & \\ q 2 ( x , t ) = h 2 ( {T}_{liquid} - {T}_{wafer} ) & ( Formulation 6 )\end{matrix}$$

Where h1 and h2 represent heat transfer coefficients, and T_{ref} represents a temperature (room temperature) of an atmosphere. The heat transfer coefficients h1 and h2 are determined by identification based on an experimental result.

Using the governing equation (2), it is possible to calculate a temperature of a liquid film of the processing liquid while taking an inflow of heat from the outside to the processing liquid and exchange of heat between the processing liquid and an atmosphere into consideration.

The governing equation (3) is a governing equation for calculating heat transfer inside of the substrate W. It is possible to calculate a temperature of the substrate W using the governing equation (3).

The governing equation (4) is a governing equation (Arrhenius equation) that models etching reaction occurring between the substrate W and the processing liquid. By solution of the time evolution of the governing equations (1) to (3), an instantaneous value of a concentration of the processing liquid and an instantaneous value of a temperature of the substrate W at each of a plurality of different positions in the radial direction of the substrate W are calculated. By solution of this governing equation (4), an instantaneous value of the etching rate ER at a point in time is calculated with reference to an instantaneous value of a concentration of the processing liquid and an instantaneous value of a temperature of the substrate W at each of the plurality of different positions in the radial direction of the substrate W.

It is possible to obtain an integrated value of the etching amount up to the point in time by integrating the etching rate ER over time. By formulation of the governing equations (1) to (3) for solution of time evolution, and running of a cycle to calculate an etching amount using the governing equation (4), a processing result (etching profile) up to any point in time is obtained. In this manner, the CFD model is a rule-based model that performs an analysis in consideration of a physical quantity.

The CFD model includes the governing equations (1) to (3) and the governing equation (4). The governing equations (1) to (3) are a first algorithm for simulating a temperature of the substrate at each of a plurality of different positions in the radial direction of the substrate W based on a pre-processing condition. Further, the governing equation (4) is a second algorithm for simulating a pre-processing result, with the pre-processing amount indicating an integrated value of a processing amount at each of the plurality of different positions in the radial direction of the substrate W, based on a temperature of the substrate W at each of the plurality of different positions in the radial direction of the substrate W, with the temperature being predicted using the governing equations (1) to (3). Therefore, a pre-processing result is obtained based on a pre-processing condition without an actual process on the substrate W by the substrate processing device 300. Therefore, a second dataset can be easily generated.

The trainer 225A includes the pre-trainer 225c and the learning model generator 225e. The pre-trainer 225c receives the second dataset. Specifically, the pre-trainer 225c receives compressed data output from the second compressor 224e, a pre-fixed condition output from the pre-fixed condition generator 224g, and a pre-processing result output from the processing amount predictor 232. The pre-trainer 225c causes a learning model to execute machine learning using the second dataset. The learning model used in the modified example includes a neural network shown in FIG. 10.

Specifically, the pre-trainer 225c provides the pre-processing condition included in the second dataset to the learning model, and adjusts a parameter of the learning model such that a prediction processing result predicted by the learning model is brought closer to the pre-processing result included in the second dataset. Due to pre-training by the pre-trainer 225c, the learning model can execute machine learning using a variable condition having a plurality of characteristics as pre-knowledge without being biased to any of the plurality of characteristics. Hereinafter, machine learning to be executed in the pre-trainer 225c is referred to as pre-training. The pre-trainer 225c outputs a pre-trained learning model to the learning model generator 225e.

The learning model generator 225e receives a first dataset. Specifically, the learning model generator 225e receives a fixed condition and a processing result output from the data acquirer 221 and compressed data output from the first compressor 222. Further, the learning model generator 225e receives the pre-trained learning model output from the pre-trainer 225c. The learning model generator 225e causes the pre-trained learning model to further execute machine learning using the first dataset.

The learning model that is made to execute machine learning by the learning model generator 225e is the pre-trained learning model that has been pre-trained by the pre-trainer 225c. Because the pre-trained learning model has been trained using a plurality of characteristics of a variable condition, it is possible to reduce the influence of bias in regard to characteristics of the variable condition included in experimental data in machine learning using the experimental data by the learning model generator 225e, and improve prediction accuracy.

The learning model generator 225e sets a combination of the learning model that has been trained using the second dataset, and a compression device as a prediction device, and outputs the prediction device to the prediction device transmitter 230. The function of the compression device included in the prediction device is similar to the function of the first compressor 222.

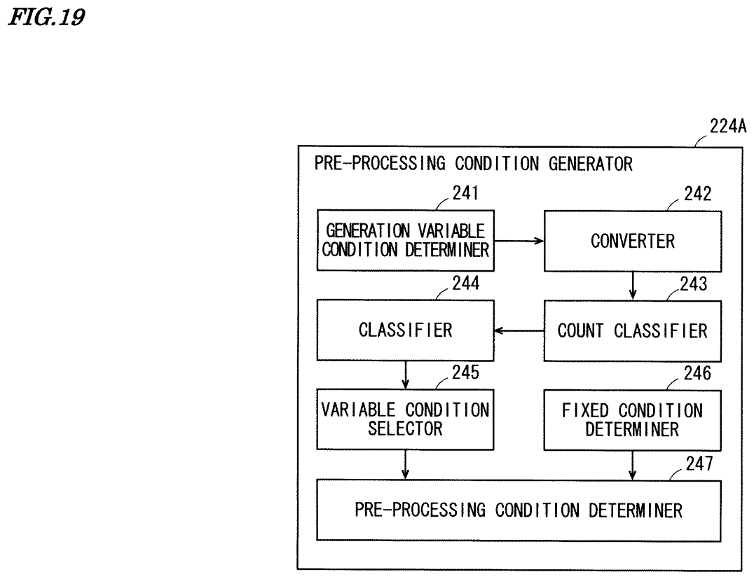

FIG. 19 is a diagram showing one example of the detailed functions of the pre-processing condition generator. With reference to FIG. 19, the pre-processing condition generator 224A includes a generation variable condition determiner 241, a converter 242, a count classifier 243, a classifier 244, a variable condition selector 245, a fixed condition determiner 246 and a pre-processing condition determiner 247.

The generation variable condition determiner 241 determines a plurality of generation variable conditions distributed over the entire valid range of variable conditions. A generation processing condition includes a generation variable condition and a generation fixed condition. The generation variable condition is a position of the nozzle 311 with respect to the substrate W, with the position changing over time. Here, the nozzle 311 reciprocates above the substrate W one or more times in a period during which the substrate processing device 300 executes a film process, and the velocity of the nozzle 311 is changed one or more times in a period during which the nozzle 311 reciprocates once, by way of example. A variable condition is defined based on a reciprocation count of the nozzle 311, the number of shift points of the nozzle 311, a velocity of the nozzle 311 set at each shift point, and a movement period of time during which the nozzle 311 moves between shift points. The velocity of the nozzle 311 includes zero. In a case in which the velocity of the nozzle 311 is zero, the nozzle 311 is stopped. Therefore, a movement period of time in a case in which the velocity of the nozzle 311 is zero is also referred to as a stop period of time. In a case in which a processing period of time during which the film process is executed is fixed, a scan period T of time per reciprocation is defined by division of the processing period of time by a reciprocation count. A shift point count indicates a shift count n. Letting a scan period T of time be a distance L (substrate diameter), and letting the average of velocity of the nozzle 311 in the scan period T of time be an average velocity Vm, 2L=T×Vm. Letting a period during which a velocity of the nozzle 311 is a constant velocity be a movement period Ti (1≤l≤n), and letting a velocity of the nozzle 311 in the movement period Ti be Vi, the following formulation (7) holds.

2L=ΣTi×Vi (7)

By determination of a combination of Ti and Vi that satisfies the above-mentioned formulation (7), a variable condition with respect to a reciprocation count and the number of shift points is defined. For example, when one of Ti and Vi is defined, the other one of Ti and Vi is defined by the formulation (7). Vi may be defined after Ti is defined, or Ti may be defined after Vi is defined. For example, Ti may be defined by equal division of the scan period T of time per reciprocation, or a plurality of patterns for division of the scan period T of time may be prepared in advance. The plurality of patterns include a pattern in which Ti gradually increases, a pattern in which Ti gradually decreases, a pattern in which Ti gradually increases and then gradually decreases, for example.

The generation variable condition determiner 241 generates a plurality of sets of the movement period Ti and the velocity Vi for each of a plurality of sets of a reciprocation count and a shift point count, thereby generating a plurality of generation variable conditions. In a case in which an upper limit value is set for each of a reciprocation count and a shift point count, the generation variable condition determiner 241 generates a plurality of sets of the movement period Ti and the velocity Vi for all combinations of a reciprocation count and a shift point count.

The plurality of generation variable conditions determined by the generation variable condition determiner 241 have different work patterns of the nozzle as described above. For example, the plurality of generation variable conditions generated by the generation variable condition determiner 241 have different values in regard to at least one of a reciprocation count, a shift point count, a movement period and a velocity. In the present embodiment, the number of the generation variable conditions determined by the generation variable condition determiner 241 is 18,000.

The converter 242 converts the plurality of generation variable conditions determined by the generation variable condition determiner 241 into conversion data pieces. The converter 242 outputs a set of a generation variable condition and a conversion data piece to the count classifier 243. A conversion data piece is a variable relating to a generation variable condition.

In the present embodiment, conversion data is set as a cumulative dwell time distribution. The cumulative dwell time distribution represents a value obtained when period of times during which the nozzle dwells at each of a plurality of positions in the radial direction of the substrate W in a processing period of time are accumulated from the center of the substrate W toward an outer periphery of the substrate W. The cumulative dwell time distribution will be described.

The cumulative dwell time distribution is obtained when, in regard to the dwell time distribution shown in FIG. 9, dwell times are accumulated sequentially from the center to the outer periphery of the substrate W. Specifically, a cumulative dwell time of the divided area b2 is the sum of a dwell time of the divided area b1 and a dwell time of the divided area b2, a cumulative dwell time of the divided area b3 is the sum of the cumulative dwell time of the divided area b2 and a dwell time of the divided area b3, and a cumulative dwell time of the divided area b15 is the sum of the cumulative dwell time of the divided area b14 and a dwell time of the divided area b15.

In the present embodiment, a variable condition is converted into conversion data, with the conversion data being a cumulative dwell time. Since a cumulative dwell time is obtained by division of the upper surface of the substrate W by fifteen divided areas b1 to b15, the number of conversion data pieces is fifteen. The longer each of the divided areas b1 to b15 in the radial direction of the substrate, the smaller the number of conversion data pieces. Because the length of each of the divided areas b1 to b15 in the radial direction of the substrate is equal to or larger than an inner diameter of the nozzle 311, a maximum value of the number of conversion data pieces is defined based on the inner diameter of the nozzle 311.

The count classifier 243 receives a plurality of sets of a generation variable condition and conversion data from the converter 242. The count classifier 243 classifies a plurality of generation variable conditions into a plurality of count-based groups based on a reciprocation count of the nozzle 311. In the present embodiment, the count classifier 243 classifies a plurality of generation conversion data pieces into a count-based group for a reciprocation count of zero to three times, a count-based group for a reciprocation count of three to six times, a count-based group for a reciprocation count of six to nine times, and a count-based group for a reciprocation count of nine or more. Although the count-based groups are classified using reciprocation counts of three, six and nine as thresholds values, other values may be used as threshold values. Further, the number of count-based groups is not limited to four, and is only required to be one or more.

Further, in regard to each of the plurality of count-based groups, the classifier 244 clusters generation variable conditions belonging to each count-based group into a plurality of groups based on conversion data.

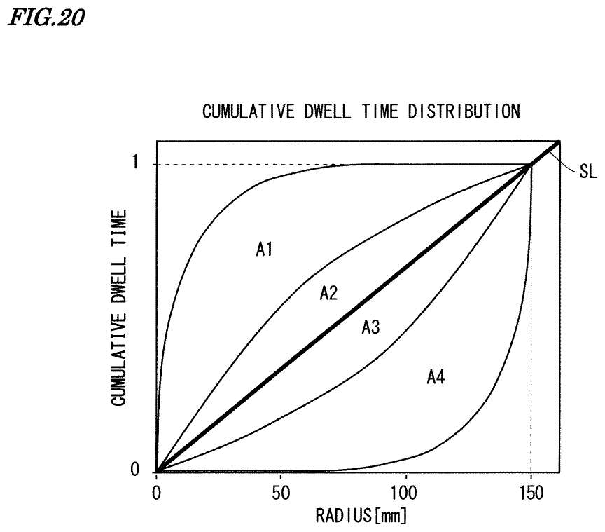

FIG. 20 is a diagram for explaining one example of a result of clustering. FIG. 20 shows the cumulative dwell time distribution of the nozzle 311 based on the substrate center OP at each position in the radial direction in regard to the cluster for a reciprocation count of zero to three times. With reference to FIG. 20, the ordinate indicates the cumulative dwell time of the nozzle from the substrate center OP, and the abscissa indicates a position in the radial direction of the substrate W. The position of the substrate center OP is indicated by 0 mm, and an end portion in the radial direction of the substrate W is indicated by 150 mm. In regard to the ordinate, the scale is normalized to one by division of a cumulative dwell time at each position in the radial direction of the substrate W by the total of cumulative dwell times. A reference line SL represents the cumulative dwell time distribution of the nozzle 311 in a case in which the nozzle 311 is present at each position in the radial direction of the substrate W for the same period of time in regard to a nozzle work pattern. Although being distributed about the reference line SL, the nozzle work pattern included in a generation variable condition is not shown.

The nozzle work pattern of the generation variable condition is clustered into areas A1 to A4, by way of example. The areas A1, A2 are symmetrical to the areas A3, A4 with respect to the reference line SL in regard to the areas A1 to A4 by way of example. Although not limited, the areas A1 to A4 may be determined by k-means method. For clustering, a method other than k-means method may be used. Further, although the nozzle work pattern is clustered into four, the number of clusters is not limited to this.

Reference back to FIG. 19, the variable condition selector 245 randomly selects one or a plurality of generation variable conditions from among generation variable conditions belonging to a cluster clustered by the classifier 244, and outputs the plurality of selected generation variable conditions to the pre-processing condition determiner 247. For example, sixty generation variable conditions are selected randomly from each of four clusters which are indicated by the areas A1 to A4 and into which a plurality of generation variable conditions belonging to the count-based group for a reciprocation count of zero to three are clustered by the classifier 244. Thus, 240 generation variable conditions are selected from the count-based group for the reciprocation count of zero to three. Further, the variable condition selector 245 also selects 240 generation variable conditions using the similar method in regard to each of the count-based group for the reciprocation count of three to six, the count-based group of reciprocation count of six to nine and the count-based group for the reciprocation count of nine or more. Therefore, the variable condition selector 245 determines 960 generation variable conditions. Thus, the variable condition selector 245 evenly selects the generation variable conditions having different characteristics of the cumulative dwell time distribution from the plurality of generation variable conditions. Therefore, it is possible to select a plurality of variable conditions which are not biased to a specific cumulative dwell time distribution.

The fixed condition determiner 246 generates a plurality of generation fixed conditions distributed over the entire valid range of a value to be set for a fixed condition, and outputs the plurality of generated generation fixed conditions to the pre-processing condition determiner 247. For example, the fixed condition determiner 246 generates, as a generation fixed condition, a fixed condition having a central value of the range obtained when the valid range of a fixed condition is divided into three equal parts. In the present embodiment, twenty seven fixed conditions which are combinations of three (3) substrate rotation speeds, three flow rates of the etching liquid, and three temperatures of the etching liquid, are determined as generation fixed conditions.

The pre-processing condition determiner 247 receives generation variable conditions from the variable condition selector 245 and receives generation fixed conditions from the fixed condition determiner 246. The pre-processing condition determiner 247 generates a plurality of processing conditions by combining the generation variable conditions and the generation fixed conditions. Further, the pre-processing condition determiner 247 determines a generation processing condition for pre-training a learning model by narrowing down the number of the plurality of generation processing conditions by, for example, pairwise testing.

In the present embodiment, the pre-processing condition determiner 247 receives the 960 generation variable conditions from the variable condition selector 245 and receives the twenty seven generation fixed conditions from the fixed condition determiner 246. The pre-processing condition determiner 247 generates 25,920 generation processing conditions by combining the 960 generation variable conditions and the twenty seven generation fixed conditions. Further, the pre-processing condition determiner 247 narrows down the 25,920 generation processing conditions to 2,716 generation processing conditions by pairwise testing. Thus, the pre-processing condition determiner 247 determines the 2,716 generation processing conditions as generation processing conditions for generating a prediction algorithm. The pre-processing condition determiner 247 outputs the 2,716 generation processing conditions. Specifically, the pre-processing condition determiner 247 outputs the generation processing conditions to the processing amount predictor 232 as pre-processing conditions, outputs generation variable conditions of the generation processing conditions to the second compressor 224e as pre-variable conditions, and outputs generation fixed conditions to the pre-trainer 225c of the trainer 225A as pre-fixed conditions.

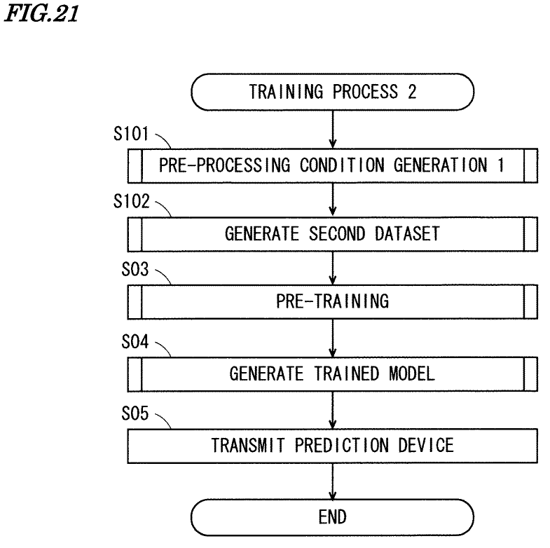

FIG. 21 is a flowchart showing one example of a flow of a training process in the modified example. The training process in the modified example is executed by execution by a CPU 201 included in the training device 200A of a training program stored in a RAM 202.

With reference to FIG. 21, the difference from the training process shown in FIG. 11 is that the step S01 and the step S02 are respectively changed to the step S101 and the step S102. The other processes are the same as those shown in FIG. 11. The description thereof will therefore not be repeated here. The CPU 201 included in the training device 200A in the modified example executes a pre-processing condition generation process (step S101). Although the details of the pre-processing condition generation process will be described below, the pre-processing condition generation process is a process of generating a plurality of pre-processing conditions including a pre-variable condition and a pre-fixed condition. Subsequently, the CPU 201 executes a second dataset generation process (step S102). Although the details of the second dataset generation process will be described below, the second dataset generation process is a process of calculating a prediction processing result based on a pre-processing condition and generating a second dataset including the pre-processing condition and the prediction processing result.

In the next step S03, the CPU 201 executes the pre-training process shown in FIG. 14. Thus, a learning model is pre-trained using the second dataset generated in the step S102. In the next step S04, the CPU 201 executes the learning model generation process shown in FIG. 15. Thus, the pre-training process is a process of causing the learning model that is pre-trained in the step S03 to execute machine learning using experimental data.

In the next step S05, the CPU 201 generates a prediction device including a learning model and a compression device, and transmits the prediction device to the information processing apparatus 100 by controlling the input-output I/F 207.

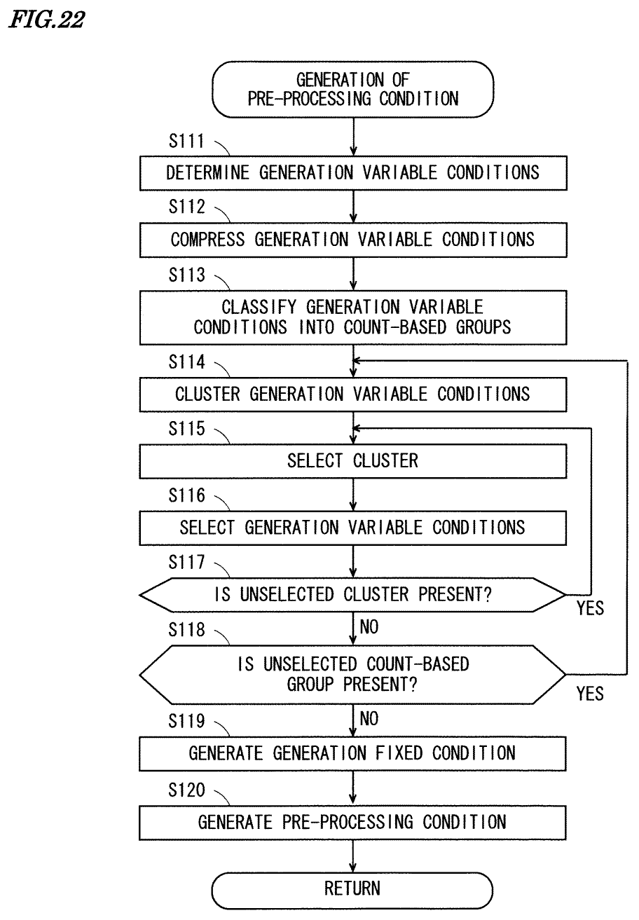

FIG. 22 is a flowchart showing one example of a flow of the pre-processing condition generation process. The pre-processing condition generation process is executed in the step S101 of the training process in the modified example. With reference to FIG. 22, the CPU 201 included in the training device 200A determines a generation variable condition (step S111). Here, a plurality of variable conditions distributed over the entire valid range of variable conditions are determined as generation variable conditions. In the next step S112, the CPU 201 converts the determined generation variable conditions into conversion data. Here, the conversion data is a cumulative dwell time distribution. The upper surface of the substrate W is divided into a plurality of areas. The cumulative dwell time distribution is obtained when a variable condition is converted into a dwell time of the nozzle in each of the plurality of divided areas, and dwell times are accumulated sequentially from the center to the outer periphery of the substrate W.

In the step S113, the CPU 201 classifies the generation variable conditions into a plurality of count-based groups. Here, the plurality of generation variable conditions are classified into the plurality of count-based groups based on a reciprocation count of the nozzle 311. In the step S114, the CPU 201 selects one count-based group, and clusters a plurality of generation variable conditions included in the selected count-based group using the conversion data. When the plurality of generation variable conditions are clustered based on the conversion data, one or more clusters are specified. A plurality of generation variable conditions belong to each of the one or more clusters. Subsequently, the CPU 201 selects a cluster to be processed from among the plurality of clusters specified by clustering (step S115), and selects a generation variable condition from the selected cluster (step S116). In the step S116, the CPU 201 randomly selects a predetermined number of generation variable conditions from among the plurality of generation variable conditions belonging to the cluster selected to be processed. The predetermined number is an integer equal to or larger than one.

In the step S117, the CPU 201 determines whether an unselected cluster is present among the one or more clusters specified by clustering. In a case in which an unselected cluster is present, the process returns to the step S115. Thus, the process of the steps S115 and S116 is repeated in regard to all of the one or more clusters specified by clustering. In this case, because the predetermined number of generation variable conditions are selected from each of the one or more clusters specified by clustering in regard to one count-based group, generation variable conditions having different characteristics of the cumulative dwell time distribution are evenly selected. In a case in which it is determined that no unselected cluster is present in the step S117, the process proceeds to the step S118.

In the step S118, the CPU 201 determines whether an unselected count-based group is present. In a case in which an unselected count-based group is present, the process returns to the step S114. Thus, the process of the steps S114 to step S117 is executed in regard to all of the plurality of count-based groups. In this case, because different generation processing conditions are to be clustered because of having different reciprocation counts of the nozzle 311, this is effective in a case in which processing amounts are different due to differences in reciprocation count of the nozzle 311. In a case in which it is determined that no unselected count-based group is present in the step S118, the process proceeds to the step S119.

The CPU 201 generates a generation fixed condition in the step S119, and the process proceeds to the step S120. Here, a plurality of variable conditions distributed over the entire valid range of a value to be set for a fixed condition are generated as generation fixed conditions. In the step S120, the CPU 201 generates a plurality of pre-processing conditions by combining generation variable conditions and generation fixed conditions.

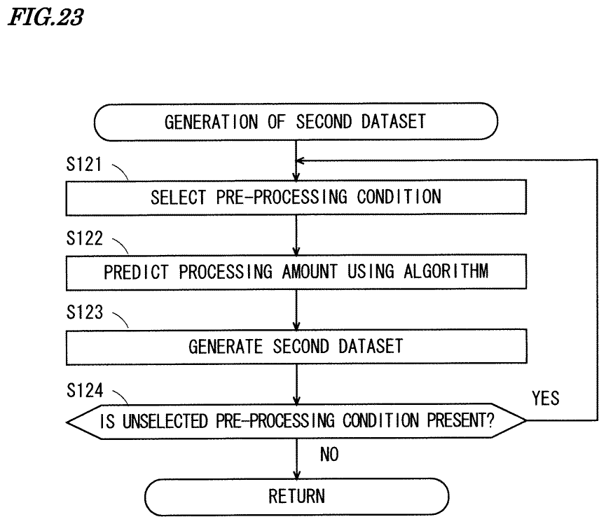

FIG. 23 is a flowchart showing one example of a flow of the second dataset generation process. The second dataset generation process is executed in the step S102 of the training process in the modified example. With reference to FIG. 23, the CPU 201 selects a pre-processing condition to be processed (step S121). In the next step S122, the CPU 201 calculates a processing amount using an algorithm. A processing amount at each of a plurality of different positions in the radial direction of the substrate is calculated. A processing amount for each of the plurality of positions is a processing result. Then, the CPU 201 generates a second dataset, and the process proceeds to the step S124. A second dataset including the pre-processing condition selected in the step S121 to be processed and a processing result including the processing amount calculated in the step S122 is generated.

In the next step S124, the CPU 201 determines whether an unselected pre-processing condition is present. If a pre-processing condition that is not selected in the step S121 to be processed is present, the process returns to the step S121. If not, the process returns to the training process.

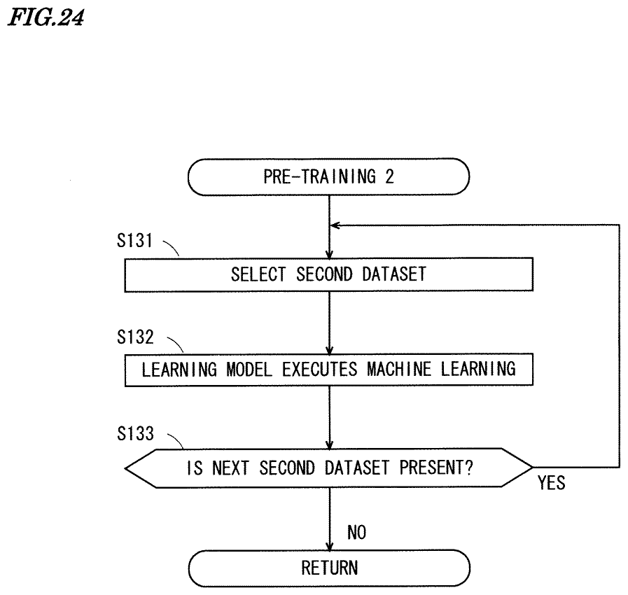

FIG. 24 is a flowchart showing one example of a flow of the pre-training process in the modified example. The pre-training process is executed in the step S03 of the training process. The second dataset is generated before the pre-training process is executed. With reference to FIG. 24, the CPU 201 selects a second dataset to be processed (step S131), and the process proceeds to the step S132. In the step S132, the CPU 201 causes a learning model to execute machine learning using the second dataset, and the process proceeds to the step S133. In the step S133, whether a second dataset to be processed next is present is determined. If an unselected second dataset is present, the process returns to the step S131. If not, the process returns to the training process. The process of the steps S131 to 133 is repeated for the number of first epochs.

### (5) Effects of Embodiment

With the training device 200 of the above-mentioned embodiment, because a prediction algorithm that has been trained using experimental data is generated, it is possible to generate a pre-processing condition and a prediction processing result separately from experimental data. This pre-processing condition can include a plurality of processing conditions distributed over the entire valid range of processing conditions for execution of a process by the substrate processing device 300. Therefore, by pre-training the learning model using the pre-processing condition and the prediction processing result, it is possible to provide prior knowledge to the learning model. Then, because the pre-trained learning model to which the prior knowledge is provided is trained using the experimental data, the accuracy can be improved as compared with a prediction algorithm that has been trained only using the experimental data. Further, because the number of experimental data pieces may be the number necessary for generation of the prediction algorithm, it is possible to suppress the cost for generating the experimental data to be used in machine learning for the learning model. As a result, it is possible to provide the training device 200 capable of generating a highly accurate learning model at low cost.

Further, because the prediction algorithm and the learning model are the same, it is only required to prepare a single learning model, and it is possible to easily generate the learning model.

With the substrate processing device 300 of the above-mentioned embodiment, in a case in which a temporary processing condition is provided to a pre-trained learning model and a processing result predicted by the learning model satisfies an allowable condition, the temporary processing condition is determined as a processing condition for driving the substrate processing device 300. Therefore, it is possible to determine a plurality of temporary processing conditions for the processing result that satisfies the allowable condition. As a result, it is possible to present a plurality of processing conditions for a processing result of a complicated process.

In the training device 200A in the modified example, a prediction algorithm is a rule-based CFD model that performs an analysis in consideration of a physical quantity. Therefore, it is possible to obtain a pre-processing result based on a pre-processing condition without an actual process on the substrate W by the substrate processing device 300. Therefore, it is possible to generate a second dataset.

Further, in the training device 200A in the modified example, a plurality of pre-processing conditions are generated. The pre-processing conditions include a plurality of processing conditions having a plurality of variable conditions distributed over the valid range of a variable condition. At this time, a plurality of processing conditions distributed over the valid range of a processing condition are classified into a plurality of groups, and the training device 200A selects at least one processing condition from the plurality of groups. Therefore, it is possible to select a plurality of processing conditions with less bias that encompass the valid range of processing conditions. Further, the training device 200A generates a learning model that has executed machine learning using the second dataset including a selected processing condition and a processing amount. Therefore, it is possible to improve generalization of the learning model. Further, because the number of second datasets can be suppressed, the cost for generating the second data sets can be reduced as much as possible.

### (6) Other Embodiments

(6-1) While a prediction algorithm in the above-mentioned embodiment includes the plurality of neural networks shown in FIG. 10 by way of example, the present invention is not limited to this. For example, a prediction algorithm may be a regression model that is an algorithm constructed using a predetermined regression equation. In this case, the prediction algorithm generator 223 may regress the prediction algorithm based on a first data set including a fixed condition, compressed data and a processing result, or may regress the prediction algorithm based on a dataset including a processing condition and a processing result.

(6-2) While the prediction device generator 220 includes the first compressor 222 in the above-mentioned embodiment, the present invention is not limited to this. In machine learning of a prediction algorithm, the first compressor 222 does not have to be provided. This is particularly effective in a case in which the number of dimensions of a variable condition is small. While the pre-processing condition generator 224 of the prediction device generator 220 similarly includes the second compressor 224e, the present invention is not limited to this. In the pre-training of a learning model, the second compressor 224e does not have to be provided. This is particularly effective in a case in which the number of dimensions of a variable condition is small.

Further, although the first compressor 222 and the second compressor 224e generate compressed data that is obtained when a variable condition is converted into a dwell time of the nozzle in each of a plurality of areas, by way of example, the present invention is not limited to this. A learning model that has executed machine learning using an autoencoder may be used as the first compressor 222 and the second compressor 224e.

(6-3) While a prediction algorithm includes the first convolutional neural network in the above-mentioned embodiment, the present invention is not limited to this. The prediction algorithm does not have to include the first convolutional neural network CNN1. In this case, compressed data in which a variable condition is compressed is directly input to the first fully-connected neural network NN1.

(6-4) Although the CFD model is a prediction algorithm used by the training device 200A in the modified example by way of example, the present invention is not limited to this. A prediction algorithm is only required to be a rule-based model that performs an analysis in consideration of a physical quantity in order to calculate a processing result using a processing condition.

(6-5) In the above-mentioned embodiment, the temporary variable condition generator 224a, the pre-variable condition determiner 224c and the pre-fixed condition generator 224g included in the pre-processing condition generator 224 shown in FIG. 5 may be replaced with the generation variable condition determiner 241 in the modified example shown in FIG. 19.

### (7) Overview of Embodiments

(Item 1) A training device according to one aspect of the present invention includes an experimental data acquirer that acquires a first dataset including a processing condition for a process to be executed by a substrate processing device, and a processing result of the process, a pre-processing condition generator that generates a pre-processing condition, a pre-trainer that causes a learning model to execute machine learning using the second dataset, and a learning model generator that causes the trained learning model to execute machine learning using the first dataset, with the trained learning model being made by the pre-trainer to execute machine learning, wherein the second dataset includes a pre-processing result that is predicted by a predetermined prediction algorithm based on the pre-processing condition, and the pre-processing condition.

The training device according to item 1 can generate, using the predetermined prediction algorithm, the pre-processing condition and the pre-processing result separately from experimental data. This pre-processing condition includes a plurality of processing conditions distributed over the entire valid range of processing conditions for execution of a process by the substrate processing device. Therefore, by pre-training the learning model using the pre-processing condition and the pre-processing result, it is possible to provide prior knowledge to the learning model. Then, because the pre-trained learning model to which the prior knowledge is provided is trained using the experimental data, the accuracy can be improved as compared with a prediction algorithm that has been trained only using the experimental data. Further, because the number of experimental data pieces may be the number necessary for generation of the prediction algorithm, it is possible to suppress the cost for generating the experimental data to be used in machine learning by the learning model. As a result, it is possible to provide the training device capable of generating a highly accurate learning model at low cost.

(Item 2) The training device according to item 1, wherein the prediction algorithm is a rule-based prediction algorithm that analyzes the pre-processing condition according to a predetermined rule.

With the training device according to item 2, because the prediction algorithm is a rule-based model that performs an analysis in consideration of a physical quantity, it is possible to obtain the pre-processing result based on the pre-processing condition without an actual process on a substrate by the substrate processing device. Therefore, it is possible to easily generate a second dataset.

(Item 3) The training device according to item 1, wherein the prediction algorithm includes a first algorithm that simulates, based on the pre-processing condition, a temperature of the substrate at each of a plurality of different positions in a radial direction of a substrate to be processed in the process by the substrate processing device, and a second algorithm that simulates, based on the temperature of the substrate at each of the plurality of positions, a result for each of the plurality of positions of the process executed by the substrate processing device, with the temperature being predicted using the first algorithm.

With the training device according to item 3, because the prediction algorithm is a rule-based model that performs an analysis in consideration of a physical quantity, it is possible to obtain the pre-processing result based on the pre-processing condition without an actual process on a substrate by the substrate processing device. Therefore, it is possible to easily generate a second dataset.

(Item 4) The training device according to item 3, wherein the process executed by the substrate processing device is a film process of supplying a processing liquid to the substrate and processing a film formed on the substrate, and the first algorithm includes an algorithm that simulates an amount of the processing liquid for each of the plurality of positions, and an algorithm that simulates a change in heat inside of the substrate, the processing liquid, and a plurality of media including a space surrounding the substrate, and thermal conduction between two media that comes into contact with each other among the plurality of media.

With the training device according to item 4, the first algorithm includes an algorithm for simulating an amount of a processing liquid, and an algorithm for simulating a change of heat in each of a plurality of media and thermal conduction between two media that come into contact with each other. Therefore, it is possible to improve prediction accuracy in regard to a temperature of the substrate at each of the plurality of positions.

(Item 5) The training device according to any one of items 1 to 4, further includes a second dataset generator that generates, as the second dataset, a dataset including a prediction processing result and the pre-processing condition, with the prediction processing result being calculated by the prediction algorithm when the pre-processing condition is provided to the prediction algorithm.

With the training device according to item 5, the second dataset including the prediction processing result that is calculated when the pre-processing condition is provided to the prediction algorithm is generated. Therefore, it is not necessary for the substrate processing device to actually process the substrate, and the second dataset can be generated.

(Item 6) The training device according to item 1, further includes a prediction algorithm generator that generates, using the first dataset, the prediction algorithm based on the processing condition.

(Item 7) The training device according to item 6, wherein the prediction algorithm may be a trained model that has executed machine learning using the first dataset.

(Item 8) The training device according to any one of items 1 to 7, wherein the substrate processing device may execute the process by supplying a processing liquid to a substrate through a nozzle a relative position of which with respect to the substrate changes over time, the processing condition may include a variable condition in which a relative position of the nozzle with respect to the substrate changes over time, the training device may further include a compressor that generates compressed data in which the variable condition is compressed, and the learning model generator may cause the learning model to execute machine learning using the compressed data, with the compressed data being obtained when the variable condition is compressed by the compressor.

With the training device according to claim 8, because the number of dimensions of the variable condition is small, it is possible to improve generalization of a learning model.

(Item 9) An information processing apparatus according to another aspect of the present invention that manages the substrate processing device using the learning model, with the learning model being generated by the training device according to any one of items 1 to 8, includes an acquirer that acquires the learning model from the training device, and a processing condition determiner that, in a case in which a prediction processing result satisfies an allowable condition, determines a temporary processing condition as a processing condition for driving the substrate processing device, with the prediction processing result being predicted by the learning model when the temporary processing condition is provided to the learning model.

With the substrate processing device according to item 9, in a case in which the temporary processing condition is provided to the pre-trained learning model, and the processing result predicted by the learning model satisfies the allowable condition, the temporary processing condition is determined as the processing condition for driving the substrate processing device 300. Therefore, it is possible to determine a plurality of temporary processing conditions for the processing result that satisfies the allowable condition. As a result, it is possible to present a plurality of processing conditions for a processing result of a complicated process.

(Item 10) A substrate processing device according to yet another aspect of the present invention includes the information processing apparatus according to item 9.

With the substrate processing device according to item 10, it is possible to present a plurality of processing conditions for a processing result of a complicated process of processing a substrate.

(Item 11) A training method according to yet another aspect of the present invention includes a step of acquiring a first dataset that includes a processing condition for a process executed by a substrate processing device, and a processing result of the process, a step of generating a pre-processing condition, a pre-training step of causing a learning model to execute machine learning using a second dataset, and a learning model generating step of causing the trained learning model to execute machine learning using the first dataset, with the trained learning model executing machine learning in the pre-training step, wherein the second dataset includes a pre-processing result and the pre-processing condition, with the pre-processing result being predicted by a predetermined prediction algorithm based on the pre-processing condition.

With the training method according to item 11, because the pre-trained learning model to which the prior knowledge is provided is trained using the experimental data, the accuracy can be improved as compared with a prediction algorithm that is trained only using the experimental data. Further, because the number of experimental data pieces is only required to be the number necessary for generation of the prediction algorithm, it is possible to suppress the cost for generating the experimental data to be used in machine learning by the learning model.

(Item 12) A processing condition determination method according to yet another aspect of the present invention executed by an information processing apparatus using the learning model generated by a training device that executes the above-mentioned training method, with the information processing apparatus managing the substrate processing device, includes an acquiring step of acquiring the learning model from the training device, and a processing condition determination step of, in a case in which a prediction processing result satisfies an allowable condition, determining a temporary processing condition as a processing condition for driving the substrate processing device, with the prediction processing result being predicted by the learning model when the temporary processing condition is provided to the learning model.

With the processing condition determination method according to item 12, it is possible to present the processing condition determination method with which it is possible to present a plurality of processing conditions for a result of a complicated process.

1. A training device comprising a first hardware processor, wherein
the first hardware processor
acquires a first dataset including a processing condition for a process to be executed by a substrate processing device, and a processing result of the process,
generates a pre-processing condition;
causes a learning model to execute machine learning using the second dataset, and
causes the trained learning model to execute machine learning using the first dataset, with the trained learning model having executed machine learning using the second data set, and
the second dataset includes a pre-processing result that is predicted by a predetermined prediction algorithm based on the pre-processing condition, and the pre-processing condition.

2. The training device according to claim 1, wherein
the prediction algorithm is a rule-based prediction algorithm that analyzes the pre-processing condition according to a predetermined rule.

3. The training device according to claim 1, wherein
the prediction algorithm includes
a first algorithm that simulates, based on the pre-processing condition, a temperature of the substrate at each of a plurality of different positions in a radial direction of a substrate to be processed in the process by the substrate processing device, and
a second algorithm that simulates, based on the temperature of the substrate at each of the plurality of positions, a result for each of the plurality of positions of the process executed by the substrate processing device, with the temperature being predicted using the first algorithm.

4. The training device according to claim 3, wherein
the process executed by the substrate processing device is a film process of supplying a processing liquid to the substrate and processing a film formed on the substrate, and
the first algorithm includes
an algorithm that simulates an amount of the processing liquid for each of the plurality of positions, and
an algorithm that simulates a change in heat inside of the substrate, the processing liquid, and a plurality of media including a space surrounding the substrate, and thermal conduction between two media that comes into contact with each other among the plurality of media.

5. The training device according to claim 1, wherein the first hardware processor generates, as the second dataset, a dataset including a prediction processing result and the pre-processing condition, with the prediction processing result being calculated by the prediction algorithm when the pre-processing condition is provided to the prediction algorithm.

6. The training device according to claim 1, wherein the first hardware processor generates, using the first dataset, the prediction algorithm based on the processing condition.

7. The training device according to claim 6, wherein
the prediction algorithm is a trained model that has executed machine learning using the first dataset.

8. The training device according to claim 1, wherein
the substrate processing device executes the process by supplying a processing liquid to a substrate through a nozzle a relative position of which with respect to the substrate changes over time,
the processing condition includes a variable condition in which a relative position of the nozzle with respect to the substrate changes over time,
the first hardware processor generates compressed data in which the variable condition is compressed, and
execution of machine learning using the first dataset includes causing the learning model to execute machine learning using the compressed data, with the compressed data being obtained when the variable condition is compressed.

9. An information processing apparatus that manages the substrate processing device using the learning model, the learning model being generated by the training device according to claim 1, comprising:
a second hardware processor, wherein
the second hardware processor acquires the learning model from the training device, and
in a case in which a prediction processing result satisfies an allowable condition, determines a temporary processing condition as a processing condition for driving the substrate processing device, the prediction processing result being predicted by the learning model when the temporary processing condition is provided to the learning model.

10. A substrate processing device comprising the information processing apparatus according to claim 9.

11. A training method including:
acquiring a first dataset that includes a processing condition for a process executed by a substrate processing device, and a processing result of the process;
generating a pre-processing condition;
causing a learning model to execute machine learning using a second dataset; and
causing the trained learning model to execute machine learning using the first dataset, the trained learning model having executed machine learning using the second dataset, wherein
the second dataset includes a pre-processing result and the pre-processing condition, with the pre-processing result being predicted by a predetermined prediction algorithm based on the pre-processing condition.

12. A processing condition determination method executed by an information processing apparatus using the learning model generated by a training device that executes the training method according to claim 11, the information processing apparatus managing the substrate processing device, including:
acquiring the learning model from the training device; and
in a case in which a prediction processing result satisfies an allowable condition, determining a temporary processing condition as a processing condition for driving the substrate processing device, the prediction processing result being predicted by the learning model when the temporary processing condition is provided to the learning model.
